(19) United States
(12) Patent Application Publication
(10) Pub. No.: US 2026/0293404 A1
(43) Pub. Date: Sep. 24, 2026

(54) ELECTRONIC APPARATUS

(71) Applicant: Samsung Display Co., Ltd., Yongin-si (KR)

(72) Inventors: KYUNG HYUN CHOI, Yongin-si (KR); DONGHYUN SON, Yongin-si (KR); MINSEOK KIM, Yongin-si (KR)

(21) Appl. No.: 19/572,706

(22) Filed: Mar. 19, 2026

(30) Foreign Application Priority Data
Mar. 21, 2025 (KR) 10-2025-0036852

(51) Int. Cl. H10H 29/85

(52) U.S. Cl. CPC H10H 29/8517

(57) ABSTRACT

An electronic apparatus includes a display panel including a first region having a transmission region and a light-emitting region, and a second region, and an electronic module overlapping the first region, wherein the display panel includes first light-emitting elements in the light-emitting region of the first region, second light-emitting elements in the second region, a division layer in the light-emitting region of the first region and in the second region, transmission color filters in the first region overlapping the first light-emitting elements, respectively having a smaller area than the transmission region, and including a first and second transmission color filters having a different respective thicknesses, color filters in the second region and overlapping the second light-emitting elements, and a reinforcement pattern in the first region, above the division layer, and having a closed loop shape surrounding an edge of the first transmission color filter in plan view.

### CROSS-REFERENCE TO RELATED APPLICATION

The present application claims priority to, and the benefit of, Korean Patent Application No. 10-2025-0036852, filed on Mar. 21, 2025, in the Korean Intellectual Property Office, the entire disclosure of which is incorporated herein by reference.

### BACKGROUND

The present disclosure herein relates to an electronic apparatus including a color filter.

Electronic apparatuses may be composed of various electronic components, such as a display panel and an electronic module. The electronic module may include a camera, an infrared detection sensor, or a proximity sensor. The electronic module may be located under the display panel. Transmittance of a partial region of the display panel may be greater than transmittance of another partial region of the display panel. The electronic module may receive an external input through the partial region of the display panel or may provide output through the partial region of the display panel.

### SUMMARY

The present disclosure provides an electronic apparatus with an improved display property.

One or more embodiments of the present disclosure provide an electronic apparatus including a display panel including a first region having a transmission region and a light-emitting region, and a second region adjacent to the first region, and an electronic module under the display panel and overlapping the first region, wherein the display panel includes first light-emitting elements in the light-emitting region of the first region, second light-emitting elements in the second region, a division layer in the light-emitting region of the first region and in the second region, transmission color filters in the first region, respectively overlapping the first light-emitting elements, respectively having a smaller area than the transmission region, and including a first transmission color filter and a second transmission color filter having a thickness that is less than a thickness of the first transmission color filter, color filters in the second region and respectively overlapping the second light-emitting elements, and a reinforcement pattern in the first region, above the division layer, and having a closed loop shape surrounding an edge of the first transmission color filter in plan view.

The first transmission color filter may have a green color, wherein the reinforcement pattern has a blue color.

The first transmission color filter may have a green color, wherein the reinforcement pattern has a red color.

The reinforcement pattern may have a same color as the second transmission color filter.

The electronic apparatus may further include an additional reinforcement pattern surrounding a third transmission color filter of the transmission color filters having a different color from the first transmission color filter and the second transmission color filter.

The electronic apparatus may further include an additional reinforcement pattern having a different color from the reinforcement pattern and surrounding a third transmission color filter of the transmission color filters having a different color from the first transmission color filter and the second transmission color filter.

The electronic apparatus may further include an additional reinforcement pattern surrounding a third transmission color filter of the transmission color filters that has a different color from the first transmission color filter and the second transmission color filter, wherein the reinforcement pattern is in contact with the second transmission color filter or the third transmission color filter.

The electronic apparatus may further include a third transmission color filter of the transmission color filters has a different color from the first transmission color filter and the second transmission color filter, wherein the reinforcement pattern is spaced apart from the second transmission color filter or the third transmission color filter in plan view.

The electronic apparatus may further include a third transmission color filter of the transmission color filters having a different color from the first transmission color filter and the second transmission color filter, wherein a thickness of the first transmission color filter is substantially equal to a thickness of, and has a same color as, a first color filter of the color filters.

The transmission color filters may be arranged along a diagonal direction, wherein the first transmission color filter and the transmission region are alternately arranged along a horizontal direction or a vertical direction.

The transmission color filters may be alternately arranged with the transmission region along a horizontal direction or a vertical direction, wherein the second transmission color filter is spaced apart from the first transmission color filter in the vertical direction, and wherein a third transmission color filter of the transmission color filters is spaced apart from the first transmission color filter and the second transmission color filter in the horizontal direction.

In one or more embodiments of the present disclosure, an electronic apparatus includes a display panel including a first region having transmission regions, and a second region adjacent to the first region, and an electronic module under the display panel and overlapping the first region, wherein the display panel includes first light-emitting elements in the first region, second light-emitting elements in the second region, a division layer defining first openings respectively overlapping the first light-emitting elements, second openings respectively overlapping the second light-emitting elements, and transmission openings respectively overlapping the transmission regions, color filters respectively in the first openings, transmission color filters respectively in the second openings and including a first transmission color filter having an upper surface that is different from upper surfaces of others of the transmission color filters, and a reinforcement pattern in the first region, above the division layer, and having a closed loop shape surrounding the first transmission color filter.

The reinforcement pattern may include a same material as any of the transmission color filters.

The reinforcement pattern may include a different material from the first transmission color filter, and has a red color or a blue color.

The reinforcement pattern and the first transmission color filter may be provided in plurality, wherein the transmission color filters further include second transmission color filters, and wherein the reinforcement patterns include first patterns respectively surrounding the first transmission color filters and spaced apart, and second patterns spaced apart from the first patterns, respectively surrounding the second transmission color filters, and having a same color as the first patterns.

The reinforcement pattern and the first transmission color filter may be provided in plurality, wherein the transmission color filters further include second transmission color filters, wherein the reinforcement patterns include first patterns respectively surrounding the first transmission color filters and spaced apart, and wherein the reinforcement patterns further include second patterns spaced apart from the first patterns, respectively surrounding the second transmission color filters, and having different colors from the first patterns.

The first transmission color filter may have a different thickness from a first color filter of the color filters, wherein the transmission color filters include a second transmission color filter having a different thickness from the first transmission color filter.

The first transmission color filter may be provided in plurality, wherein the transmission color filters have a different arrangement from the color filters, and include second transmission color filters and third transmission color filters having different colors from the first transmission color filters, wherein the first transmission color filters and the second transmission color filters are alternately arranged along a first diagonal direction, and wherein the first transmission color filters and the third transmission color filters are alternately arranged along a second diagonal direction crossing the first diagonal direction.

The transmission color filters may have a different arrangement from the color filters, wherein the transmission color filters include a second transmission color filter and a third transmission color filter having different colors from the first transmission color filter, and wherein the first transmission color filter and the second transmission color filter have a smaller area than the third transmission color filter.

One of the transmission regions may have a larger area than the first transmission color filter.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a block diagram of an electronic apparatus according to one or more embodiments;

FIG. 2 shows schematic diagrams of an electronic apparatus according to various embodiments;

FIGS. 3A and 3B are perspective views of an electronic apparatus according to one or more embodiments of the present disclosure;

FIG. 4 is an exploded perspective view of an electronic apparatus according to one or more embodiments of the present disclosure;

FIG. 5 is a cross-sectional view of a display device according to one or more embodiments of the present disclosure;

FIG. 6 is a plan view of a display panel according to one or more embodiments of the present disclosure;

FIG. 7 is an enlarged plan view illustrating a partial region of a display panel according to one or more embodiments of the present disclosure;

FIGS. 8A to 8C are enlarged cross-sectional views illustrating a partial region of the display panel illustrated in FIG. 7;

FIG. 9A is a plan view illustrating a portion of a display panel according to one or more embodiments of the present disclosure;

FIG. 9B is a cross-sectional view schematically illustrating a partial region in FIG. 9A;

FIG. 10A is a plan view illustrating a portion of a display panel according to one or more embodiments of the present disclosure;

FIG. 10B is a cross-sectional view schematically illustrating a partial region in FIG. 10A; and

FIGS. 11A to 11C are plan views illustrating a portion of a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, if a first part is described as being arranged “on” a second part, this indicates that the first part is arranged at an upper side or a lower side of the second part without the limitation to the upper side thereof on the basis of the gravity direction.

Further, the phrase “in a plan view” means if an object portion is viewed from above, and the phrase “in a schematic cross-sectional view” means if a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that if an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, if a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, if a portion of a layer, a film, an area, a plate, or the like is formed on another portion, a forming direction is not limited to an upper direction but includes forming the portion on a side surface or in a lower direction. On the contrary, if a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that if an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. The terms or words used in the present specification and claims are not to be limitedly interpreted as general or dictionary meanings and should be interpreted as meanings and concepts that are consistent with aspects of the present disclosure on the basis that an inventor can be their own lexicographer to appropriately define concepts of terms to describe the embodiments in the best way.

As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

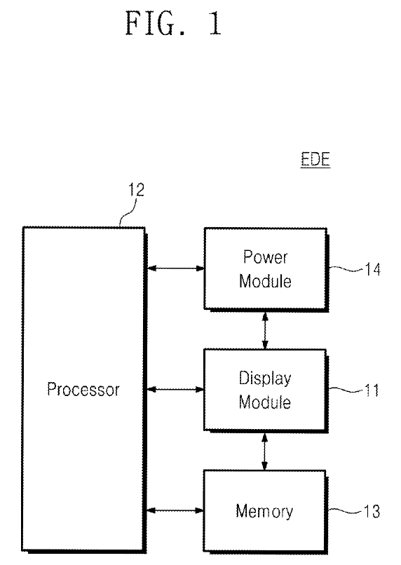

FIG. 1 is a block diagram of an electronic apparatus EDE according to one or more embodiments.

Referring to FIG. 1, the electronic apparatus EDE according to one or more embodiments may include a display module 11, a processor 12, a memory 13, and a power module 14.

The display module 11 may display an image. The image may include a static image as well as a dynamic image. The processor 12 may include at least one of a central processing unit (CPU), an application processor (AP), a graphic processing unit (GPU), a communication processor (CP), an image signal processor (ISP), or a controller. The processor 12 may be configured to control an operation of the display module 11.

In the memory 13, data information suitable for an operation of the processor 12 or the display module 11 may be stored. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or battery unit, and a power conversion module that converts the power provided by the power supply module and generates power suitable for an operation of the electronic apparatus EDE.

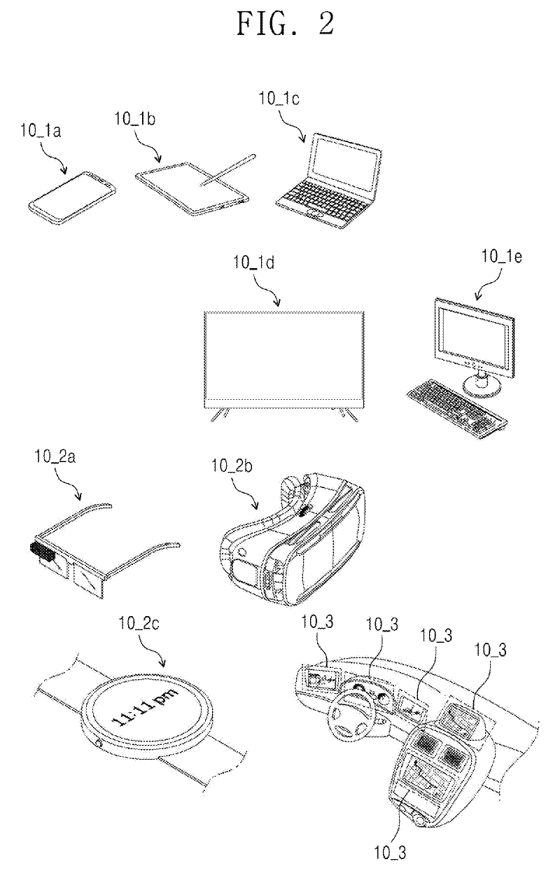

FIG. 2 shows schematic diagrams of an electronic apparatus according to various embodiments.

Referring to FIG. 2, various electronic apparatuses according to embodiments to which a display device is applied may include not only an electronic apparatus for displaying an image, such as a smart phone 10_1a, a tablet PC 10_1b, a laptop computer 10_1c, a TV 10_1d, and a monitor 10_1e for a desk, but also a wearable electronic apparatus including a display module, such as smart glasses 10_2a, a head-mounted display 10_2b, and a smart watch 10_2c, and an electronic apparatus 10_3 for vehicles including a display module, such as a room mirror display and a center information display (CID), which is located on a car’s instrument cluster, center fascia, and dashboard.

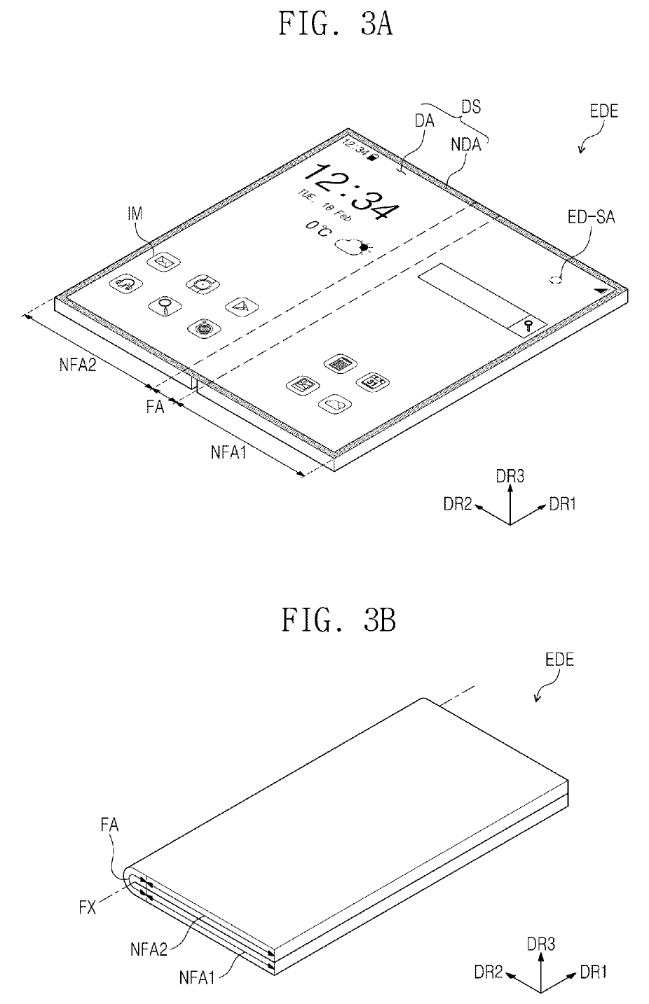

An example of some electronic apparatuses among the electronic apparatuses according to various embodiments is described in detail with reference to FIGS. 3A to 5 below.

FIGS. 3A and 3B are perspective views of an electronic apparatus EDE according to one or more embodiments of the present disclosure. FIG. 3A illustrates an unfolded state (or unfolding state) of the electronic apparatus EDE, and FIG. 3B illustrates a folded state of the electronic apparatus EDE.

Referring to FIGS. 3A and 3B, the electronic apparatus EDE according to one or more embodiments of the present disclosure may include a display surface DS defined by a first direction DR1 and by a second direction DR2 crossing the first direction DR1. The electronic apparatus EDE may provide an image IM to a user through the display surface DS.

The display surface DS may include a display region DA, and a non-display region NDA around the display region DA. The display region DA may display the image IM, and the non-display region NDA may not display the image IM. The non-display region NDA may surround the display region DA (e.g., in plan view). However, one or more embodiments is not limited thereto, and a shape of the display region DA and a shape of the non-display region NDA may be deformed.

Hereinafter, a direction substantially perpendicularly crossing a plane defined by the first direction DR1 and the second direction DR2 is defined as a third direction DR3. In addition, in this specification, the wording “on a plane,” or “in plan view,” may be defined as a “state viewed in the third direction DR3”.

A sensor region ED-SA may be defined within the display region DA of the electronic apparatus EDE. FIG. 3A illustrates one sensor region ED-SA, but the number of the sensor region ED-SA is not limited thereto. The sensor region ED-SA may be surrounded by the display region DA (e.g., in plan view).

An electronic module may be located in a region overlapping the sensor region ED-SA. The electronic module may receive an external input transmitted through the sensor region ED-SA, or may provide output through the sensor region ED-SA. For example, the electronic module may be a camera module, a sensor, such as a proximity sensor that measures distance, a sensor that recognizes a user’s body part (for example, fingerprint, iris, or face), or a small-sized lamp that outputs light, and is not particularly limited thereto. Hereinafter, the electronic module overlapping the sensor region ED-SA will be described as a camera module as an example.

The electronic apparatus EDE may include a folding region FA and a plurality of non-folding regions NFA1 and NFA2. The non-folding regions NFA1 and NFA2 may include a first non-folding region NFA1 and a second non-folding region NFA2. The folding region FA may be located between the first non-folding region NFA1 and the second non-folding region NFA2. The folding region FA may be referred to as a foldable region, and the first and second non-folding regions NFA1 and NFA2 may be referred to as first and second non-foldable regions.

As illustrated in FIG. 3B, the folding region FA may be folded with respect to a folding axis FX that is parallel to the first direction DR1. The folding region FA may have a curvature (e.g., a predetermined curvature) and a radius of curvature in a state where the electronic apparatus EDE is folded. The first non-folding region NFA1 and the second non-folding region NFA2 may face each other, and the electronic apparatus EDE may be in-folded such that the display surface DS is not exposed to the outside.

In one or more embodiments of the present disclosure, the electronic apparatus EDE may be out-folded such that the display surface DS is exposed to the outside. In one or more embodiments of the present disclosure, the electronic apparatus EDE may be in-folded or out-folded from an unfolding operation, but is not limited thereto. In one or more embodiments of the present disclosure, the electronic apparatus EDE may be configured to select any one among an unfolding operation, in-folding operation, and out-folding operation. In one or more embodiments of the present disclosure, a plurality of folding axes may be defined in the electronic apparatus EDE, and the electronic apparatus may be in-folded or out-folded from the unfolding operation on each of the plurality of folding axes.

In FIGS. 3A and 3B, the foldable electronic apparatus EDE is explained as an example, but the application of the present disclosure is not limited to the foldable electronic apparatus EDE. For example, the present disclosure may be applied to a rigid electronic apparatus, for example, an electronic apparatus without the folding region FA.

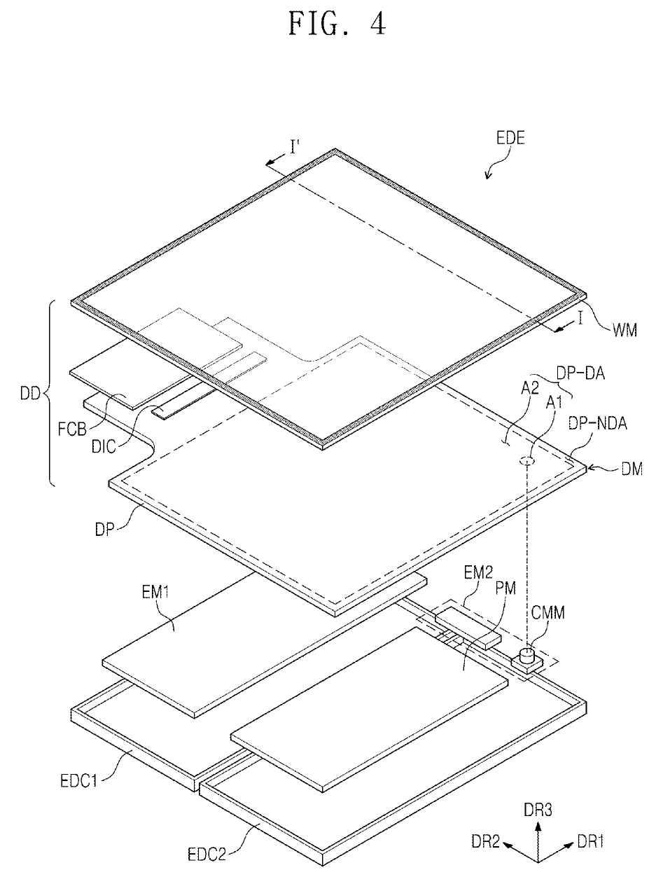

FIG. 4 is an exploded perspective view of an electronic apparatus EDE according to one or more embodiments of the present disclosure.

Referring to FIG. 4, the electronic apparatus EDE may include a display device DD, a first electronic module EM1, a second electronic module EM2, a power supply module PM, and housings EDC1 and EDC2. The electronic apparatus EDE may further include a mechanical structure for controlling a folding operation of the display device DD.

The display device DD includes a window module WM and a display module DM. The window module WM provides a front surface of the electronic apparatus EDE. The display module DM may include at least a display panel DP. The display module DM generates an image and detects an external input.

In FIG. 4, it is illustrated that the display module DM is the same as the display panel DP, but the display module DM may substantially be a stacked structure where a plurality of components including the display panel DP are stacked. The stacked structure of the display module DM will be described in detail later.

The display panel DP includes a display region DP-DA and a non-display region DP-NDA respectively corresponding to the display region DA (see FIG. 3A) and the non-display region NDA (see FIG. 3A) of the electronic apparatus EDE. In this specification, the wording “a region/portion corresponds to a region/portion” indicates “overlapping,” and is not limited to the same area.

The display region DP-DA may include a first region A1 and a second region A2. The first region A1 may correspond to or overlap the sensor region ED-SA (see FIG. 3A) of the electronic apparatus EDE. The first region A1 is illustrated as a circular shape, but the first region may have various shapes, such as a polygonal shape, oval shape, a shape with at least one curved side, or atypical shape, and is not limited to any one embodiment. The first region A1 may be referred to as a component region, and the second region A2 may be referred to as a main display region or general display region.

The first region A1 may have higher transmittance than the second region A2. The first region A1 may overlap a camera module CMM to be described later.

The display module DM may further include a driving chip DIC located on the non-display region DP-NDA. The display module DM may further include a flexible circuit film FCB coupled to the non-display region DP-NDA.

The driving chip DIC may include driving elements, for example, a data driving circuit, for driving pixels of the display panel DP. FIG. 4 illustrates a structure where the driving chip DIC is mounted on the display panel DP, but the present disclosure is not limited thereto. For example, the driving chip DIC may be mounted on the flexible circuit film FCB.

The power supply module PM supplies power suitable for an overall operation of the electronic apparatus EDE. The power supply module PM may include a typical battery module.

The first electronic module EM1 and the second electronic module EM2 may include various functional modules so as to operate the electronic apparatus EDE. The first electronic module EM1 and the second electronic module EM2 may each be directly mounted on a mother board that is electrically connected to the display panel DP, or may each be mounted on a separate board to be electrically connected to the mother board through a connector, or the like, in one or more embodiments.

The second electronic module EM2 may include the camera module CMM, a light-emitting module, a light-receiving module, and the like. The camera module CMM may capture a static image and dynamic image. The camera module CMM may be provided in plurality. Some of the camera modules CMM may overlap the first region A1. An external input (for example, light) may be provided to the camera module CMM through the first region A1. For example, the camera module CMM may capture an external image by receiving natural light through the first region A1.

The housings EDC1 and EDC2 accommodate the display module DM, the first and second electronic modules EM1 and EM2, and the power supply module PM. The housings EDC1 and EDC2 protect the components, such as the display module DM, the first and second electronic modules EM1 and EM2, and the power supply module PM, which are accommodated in the housings EDC1 and EDC2. FIG. 4 illustrates the two separate housings EDC1 and EDC2, but one or more embodiments is not limited to thereto. In one or more embodiments, the electronic apparatus EDE may further include a hinge structure for connecting the two housings EDC1 and EDC2. The housings EDC1 and EDC2 may be coupled to the window module WM.

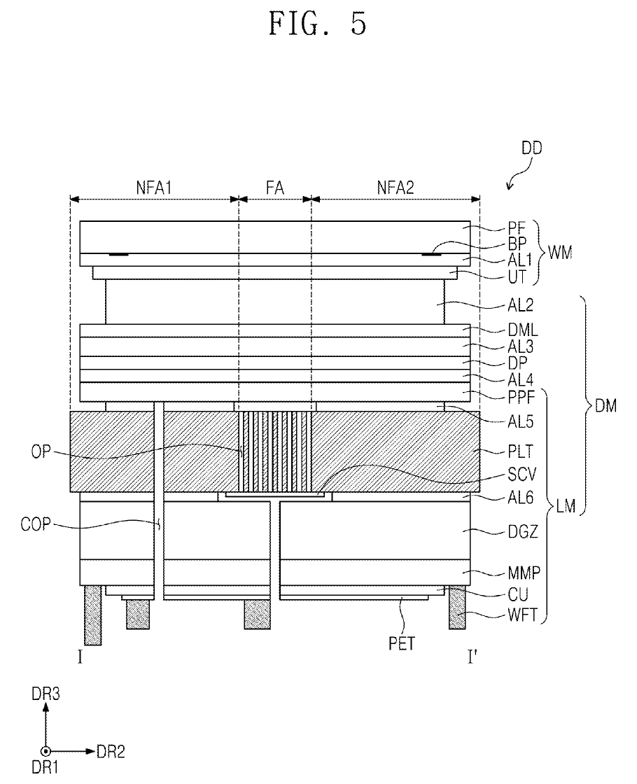

FIG. 5 is a cross-sectional view of a display device DD according to one or more embodiments of the present disclosure. FIG. 5 is a cross-sectional view of the display device DD according to one or more embodiments of the present disclosure taken along the line I-I' of FIG. 4.

Referring to FIG. 5, the display device DD may include a window module WM and a display module DM.

The window module WM may include a window UT, a protective film PF located on the window UT, and a bezel pattern BP (as used herein, “located on” may mean “above” or may mean “below”).

The window UT may be chemically strengthened glass. The window UT may be applied to the display device DD, thereby reducing or minimizing occurrence of wrinkles despite repetition of folding and unfolding.

The protective film PF may include polyimide, polycarbonate, polyamide, triacetylcellulose, polymethylmethacrylate, or polyethylene terephthalate. In one or more embodiments, at least one among a hard coating layer, anti-fingerprint layer, and anti-reflection layer may be located on an upper surface of the protective film PF.

The bezel pattern BP overlaps the non-display region NDA (see FIG. 3A). The bezel pattern BP may be located on one surface of the window UT or one surface of the protective film PF. FIG. 3 illustrates the bezel pattern BP that is located on a lower surface of the protective film PF. However, one or more embodiments is not limited thereto, and the bezel pattern BP may also be located on an upper surface of the protective film PF, an upper surface of the window UT, or a lower surface of the window UT. The bezel pattern BP may be a colored light-blocking film, and may be formed through, for example, a coating method. The bezel pattern BP may include a base material, and a dye or pigment mixed into the base material. The bezel pattern BP may have a closed loop shape on a plane (as used herein, “on a plane” may mean “plan view”).

A first adhesive layer AL1 may be located between the protective film PF and the window UT. The first adhesive layer AL1 may be a pressure sensitive adhesive (PSA) film or optically clear adhesive (OCA) member. Adhesive layers to be described below may also be the same as the first adhesive layer AL1, and may include a typical adhesive.

The first adhesive layer AL1 may have a thickness sufficient to cover the bezel pattern BP. For example, a thickness of the bezel pattern BP may be about 3 micrometers to about 8 micrometers, and the first adhesive layer AL1 may have a sufficient thickness not to cause air bubbles on the periphery of the bezel pattern BP.

The first adhesive layer AL1 may be separated from the window UT. Because strength of the protective film PF is lower than that of the window UT, scratches may occur. After the first adhesive layer AL1 and the damaged protective film PF are separated from the window UT, a new protective film PF may be attached to the window UT.

The display module DM may include an impact-absorbing layer DML, a display panel DP, and a lower member LM.

The impact-absorbing layer DML may be located on the display panel DP. The impact-absorbing layer DML may be a functional layer for protecting the display panel DP from an external impact. The impact-absorbing layer DML may be coupled to the window UT through a second adhesive layer AL2, and may be coupled to the display panel DP through a third adhesive layer AL3.

The lower member LM may be located under the display panel DP. The lower member LM may include a panel protective layer PPF, a support layer PLT, a cover layer SCV, a digitizer DGZ, a shielding layer MMP, a heat dissipation layer CU, a protective layer PET, and a waterproof tape WFT. In one or more embodiments of the present disclosure, the lower member LM may not include some of the aforementioned components, or may further include other components. In addition, a stacking sequence illustrated in FIG. 5 is only an example sequence, and the stacking sequence of the respective components may vary.

The panel protective layer PPF may be located under the display panel DP. The panel protective layer PPF may be attached to a rear surface of the display panel DP through a fourth adhesive layer AL4. The panel protective layer PPF may protect a lower portion of the display panel DP. The panel protective layer PPF may contain a flexible plastic material. The panel protective layer PPF may reduce or prevent scratches on the rear surface of the display panel DP during a process of manufacturing the display panel DP. The panel protective layer PPF may be a colored polyimide film. For example, the panel protective layer PPF may be an opaque yellow film, but is not limited thereto.

The support layer PLT is located under the panel protective layer PPF. The support layer PLT supports components located on the support layer PLT, and maintains an unfolded state or a folded state of the display device DD. In one or more embodiments of the present disclosure, the support layer PLT may include at least a first support portion corresponding to a first non-folding region NFA1, a second support portion corresponding to a second non-folding region NFA2, and a folding portion corresponding to a folding region FA. The first support portion and the second support portion may be spaced apart from each other in a second direction DR2. The folding portion may be located between the first support portion and the second support portion, and a plurality of openings OP may be defined in the folding portion. The flexibility of one portion of the support layer PLT may be improved by the openings OP. The flexibility of a portion, of the support layer PLT, overlapping the folding region FA may be improved by the openings OP.

The support layer PLT may include carbon fiber reinforced plastic (CFRP), but is not particularly limited thereto. Alternatively, the first support portion and the second support portion may include non-metallic material, plastic, glass fiber reinforced plastic, or glass. The plastic may include polyimide, polyethylene, or polyethylene terephthalate, and is not particularly limited. The first support portion and the second support portion may include the same material. The folding portion may also include the same material as the first support portion and the second support portion, and may also include a different material from the first support portion and the second support portion. For example, the folding portion may include a material with an elastic modulus of about 60 GPa or more, and may include a metal material, such as stainless steel. For example, the folding portion may include SUS 304, but is not limited thereto. The folding portion may include various metal materials.

The support layer PLT may be attached to the panel protective layer PPF through a fifth adhesive layer AL5. The fifth adhesive layer AL5 may be provided in plurality, and the fifth adhesive layers may be spaced apart from each other with the folding region FA therebetween. The fifth adhesive layer AL5 may not overlap the plurality of openings OP. In addition, on a plane, the fifth adhesive layer AL5 may be spaced apart from the plurality of openings OP. Because the fifth adhesive layer AL5 is not located in a region corresponding to the folding region FA, the flexibility of the support layer PLT may be improved.

In the region overlapping the folding region FA, the panel protective layer PPF may be spaced apart from the support layer PLT. That is, in a portion overlapping the folding region FA, empty space may be defined between the support layer PLT and the panel protective layer PPF. Because the empty space is defined between the panel protective layer PPF and the support layer PLT, a shape of the plurality of openings OP defined in the support layer PLT may not be visible from the outside of the electronic apparatus EDE (see FIG. 3A).

A thickness of the fifth adhesive layer AL5 may be less than a thickness of the fourth adhesive layer AL4. For example, the thickness of the fourth adhesive layer AL4 may be about 25 micrometers, and the thickness of the fifth adhesive layer AL5 may be about 16 micrometers. As the thickness of the fifth adhesive layer AL5 becomes smaller, a stepped portion caused by the fifth adhesive layer AL5 may be reduced. As the stepped portion becomes smaller, there may be an aspect in that shape deformation of the stacked structures due to folding and unfolding of the electronic apparatus EDE (see FIG. 3A) is reduced, but the plurality of openings OP may become visible, or the fifth adhesive layer AL5 may fall off due to repeated folding operations. As the thickness of the fifth adhesive layer AL5 becomes greater, there may be an aspect in that the plurality of openings OP are not visible, and reliability in adhesion of the fifth adhesive layer AL5 is increased by repeated folding operations, but the stepped portion may become great. Accordingly, the thickness of the fifth adhesive layer AL5 may be selected within an appropriate range in consideration of folding reliability, adhesive reliability, and visibility of the plurality of openings OP.

The cover layer SCV may be located under the support layer PLT. The cover layer SCV may be coupled to the support layer PLT by an adhesive member. The cover layer SCV may cover the plurality of openings OP defined in the support layer PLT. Accordingly, the cover layer SCV may reduce or prevent foreign matters introduced to the plurality of openings OP. The cover layer SCV may have a lower elastic modulus than the support layer PLT. For example, the cover layer SCV may include thermoplastic polyurethane, rubber, and silicon, but is not limited thereto.

The digitizer DGZ may be located under the support layer PLT. The digitizer DGZ may be provided in plurality. For example, the plurality of digitizers DGZ may be spaced apart in the second direction DR2. A portion of each of the plurality of digitizers DGZ may overlap the non-folding region NFA1 or NFA2, and a remaining portion may overlap the folding region FA. On a plane, a portion of each of the plurality of digitizers DGZ may overlap a portion of the plurality of openings OP.

The plurality of digitizers DGZ may each include multiple loop coils that generate a magnetic field at a preset resonant frequency with an input unit (hereinafter, pen). The plurality of digitizers DGZ may also be referred to as an EMR-sensing (electromagnetic resonance-sensing) panel.

The magnetic field formed in the plurality of digitizers DGZ is applied to a LC resonance circuit composed of an inductor (coil) of the pen and a capacitor. The coil generates a current in response to the received magnetic field, and the generated current is transmitted to the capacitor. Accordingly, the capacitor charges the current input from the coil, and discharges the charged current to the coil. Finally, the magnetic field of the resonant frequency is emitted in the coil. The magnetic field emitted by the pen may be reabsorbed by the loop coil of the plurality of digitizers DGZ, and thus it is possible to determine which position of the plurality of digitizers DGZ the pen is adjacent to.

The shielding layers MMP may be respectively located under the plurality of digitizers DGZ. The shielding layers MMP may each include magnetic metal powder. The shielding layers MMP may be referred to as a magnetic metal powder layer, magnetic layer, magnetic circuit layer, or magnetic path layer. The shielding layers MMP may shield a magnetic field.

The heat dissipation layers CU may be respectively located under the shielding layers MMP. The heat dissipation layers CU may be a sheet with high thermal conductivity. For example, the heat dissipation layers CU may each include graphite, copper, or copper alloy, but is not particularly limited thereto.

In one or more embodiments of the present disclosure, the digitizers DGZ and the shielding layers MMP may be omitted. In this case, the heat dissipation layers CU may be coupled to a lower portion of the support layer PLT.

The protective layers PET may be respectively located under the heat dissipation layers CU. The protective layers PET may be an insulation layer. For example, the protective layers PET may be a layer provided so as to reduce or prevent inflow of static electricity. Accordingly, electrical interference between the flexible circuit film FCB (see FIG. 4) and the members located on the protective layers PET may be reduced or prevented by the protective layers PET.

The waterproof tapes WFT may be attached to the shielding layers MMP and the protective layers PET. The waterproof tape WFT may be attached to a set bracket, in one or more embodiments. Among the waterproof tapes WFT, a thickness of the waterproof tape attached to the shielding layers MMP and a thickness of the waterproof tape attached to the protective layers PET may be different.

A penetration hole COP may be defined in at least some of the components that constitute the lower member LM. The penetration hole COP may correspond to or overlap the sensor region ED-SA (see FIG. 3A) of the electronic apparatus EDE. At least a portion of the camera module CMM (see FIG. 4) may be inserted into the penetration hole COP.

FIG. 5 illustrates that the penetration hole COP is provided from, or extending from, a rear surface of one protective layer among the protective layers PET to the fifth adhesive layer AL5, but is not limited thereto. For example, the penetration hole COP may also be provided from the rear surface of the one protective layer to the upper surface of the panel protective layer PPF, or from the rear surface of the one protective layer to the upper surface of the fourth adhesive layer AL4.

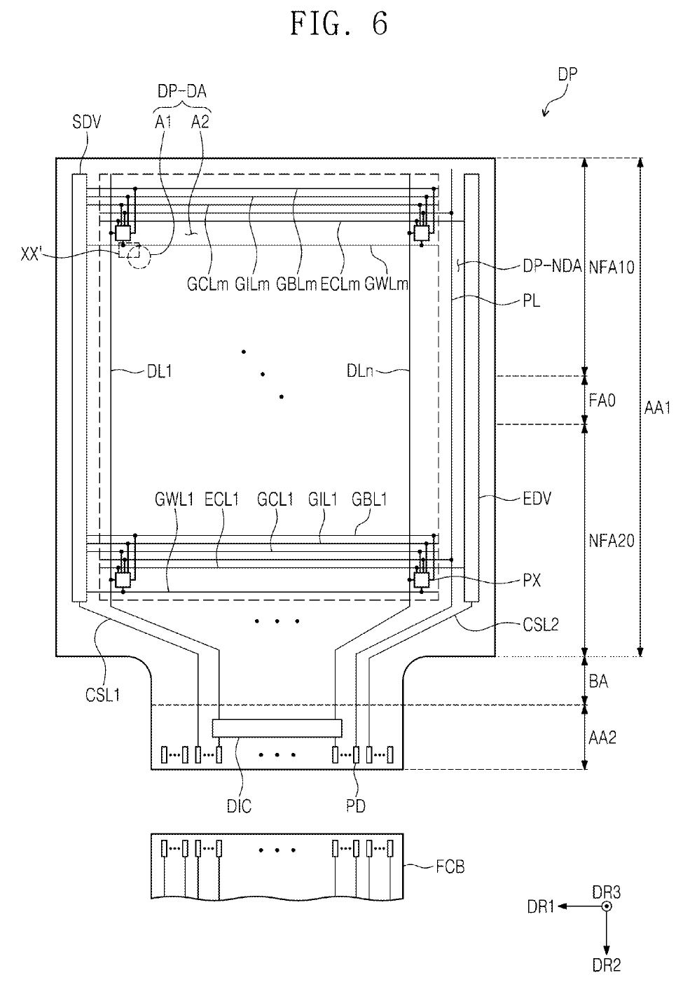

FIG. 6 is a plan view of a display panel DP according to one or more embodiments of the present disclosure.

Referring to FIG. 6, a display region DP-DA and a non-display region DP-NDA around the display region DP-DA may be defined in the display panel DP. The display region DP-DA and the non-display region DP-NDA may be distinguished by whether or not a pixel PX is present. The pixel PX is located in the display region DP-DA. A scan driver SDV, a data driver, and an emission driver EDV may be located in the non-display region DP-NDA. The data driver may be a part of a circuit configured in a driving chip DIC.

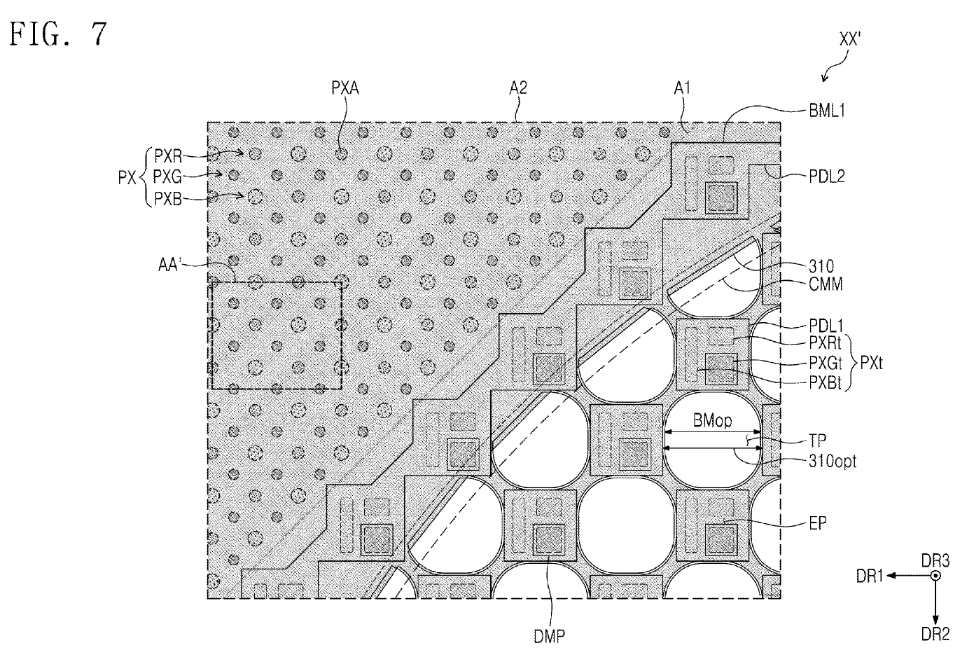

The display region DP-DA may include a first region A1 and a second region A2. The first region A1 and the second region A2 may be distinguished by presence or absence of a transmission region TP (see FIG. 7). A detailed description of the first region A1 and the second region A2 will be given later.

The display panel DP may include a first panel region AA1, a bending region BA, and a second panel region AA2 that are defined along a second direction DR2. The second panel region AA2 and the bending region BA may be a partial region of the non-display region DP-NDA. The bending region BA may be located between the first panel region AA1 and the second panel region AA2.

The first panel region AA1 may be a region corresponding to the display surface DS in FIG. 3A. The first panel region AA1 may include a first non-folding region NFA10, a second non-folding region NFA20, and a folding region FA0. The first non-folding region NFA10, the second non-folding region NFA20, and the folding region FA0 respectively correspond to the first non-folding region NFA1, the second non-folding region NFA2, and the folding region FA in FIGS. 3A and 3B.

A width of the bending region BA parallel to a first direction DR1 and a width (or length) of the second panel region AA2 may be less than a width (or length) of the first panel region AA1 parallel to the first direction DR1. A region where a length in a bending axis direction is short may be bent more suitably.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, and a plurality of pads PD. Here, m and n are natural numbers greater than or equal to 2.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 to be electrically connected to the scan driver SDV. The data lines DL1 to DLn may extend in the second direction DR2 to be electrically connected to the driving chip DIC via the bending region BA. The emission control lines ECL1 to ECLm may extend in the first direction DR1 to be electrically connected to the emission driver EDV.

The driving voltage line PL may include a portion extending in the first direction DR1 and a portion extending in the second direction DR2. The portion extending in the first direction DR1 and the portion extending in the second direction DR2 may be located on different respective layers. The portion extending in the second direction DR2 of the driving voltage line PL may extend to the second panel region AA2 via the bending region BA. The driving voltage line PL may provide a driving voltage to the pixels PX.

The first control line CSL1 may be connected to the scan driver SDV, and may extend toward a lower end of the second panel region AA2 via the bending region BA. The second control line CSL2 may be connected to the emission driver EDV, and may extend toward the lower end of the second panel region AA2 via the bending region BA.

When viewed on a plane (e.g., in plan view), the pads PD may be located adjacent to the lower end of the second panel region AA2. The driving chip DIC, the driving voltage line PL, the first control line CSL1, and the second control line CSL2 may be electrically connected to the pads PD. A flexible circuit film FCB may be electrically connected to the pads PD through an anisotropic conductive adhesive layer.

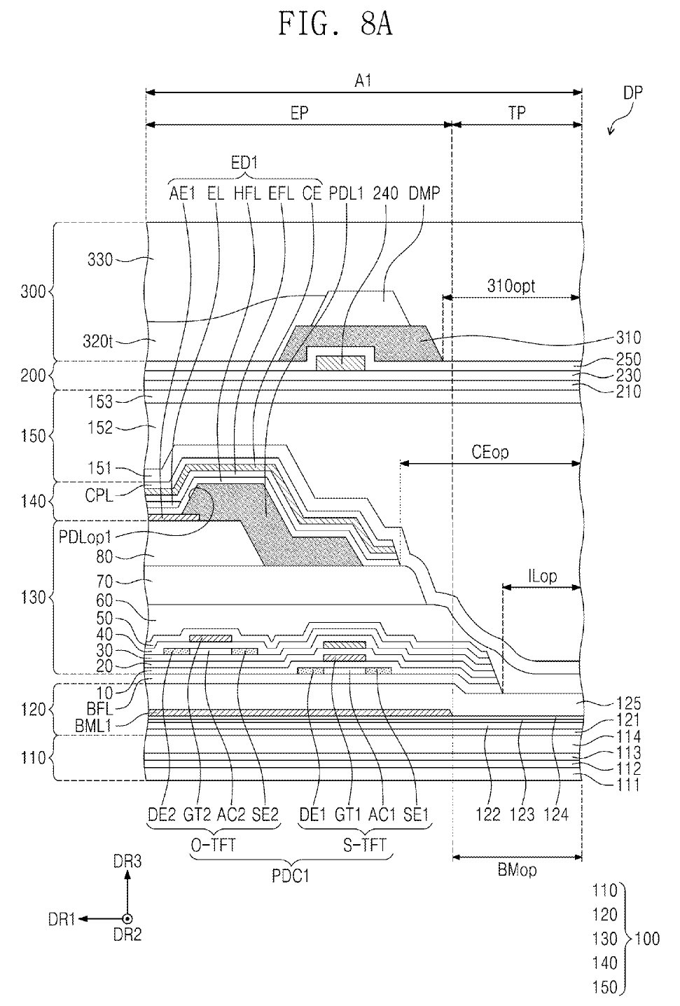

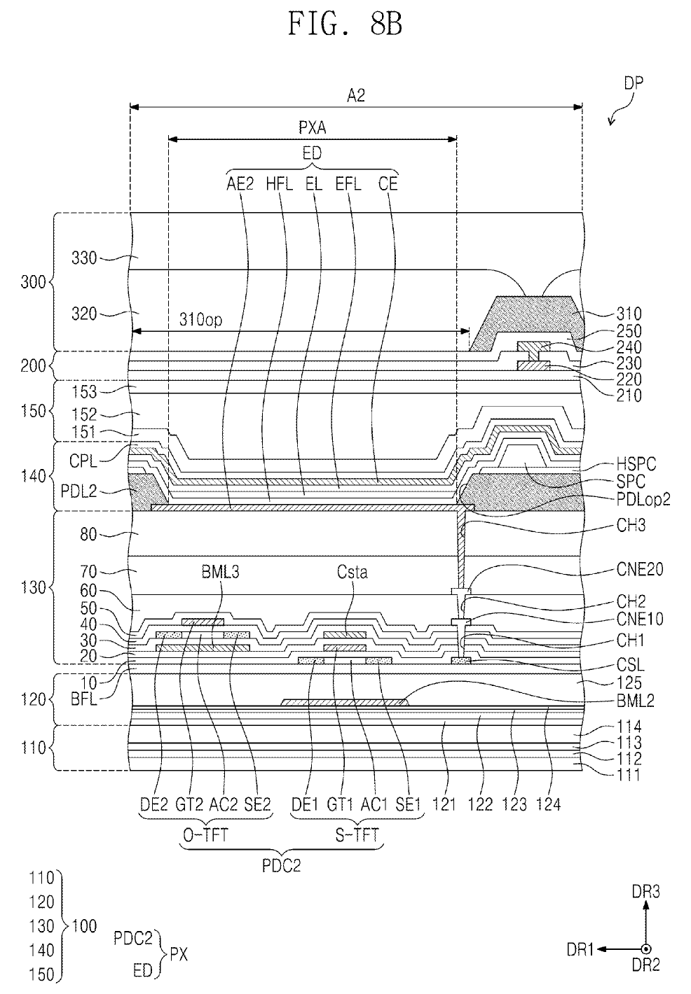

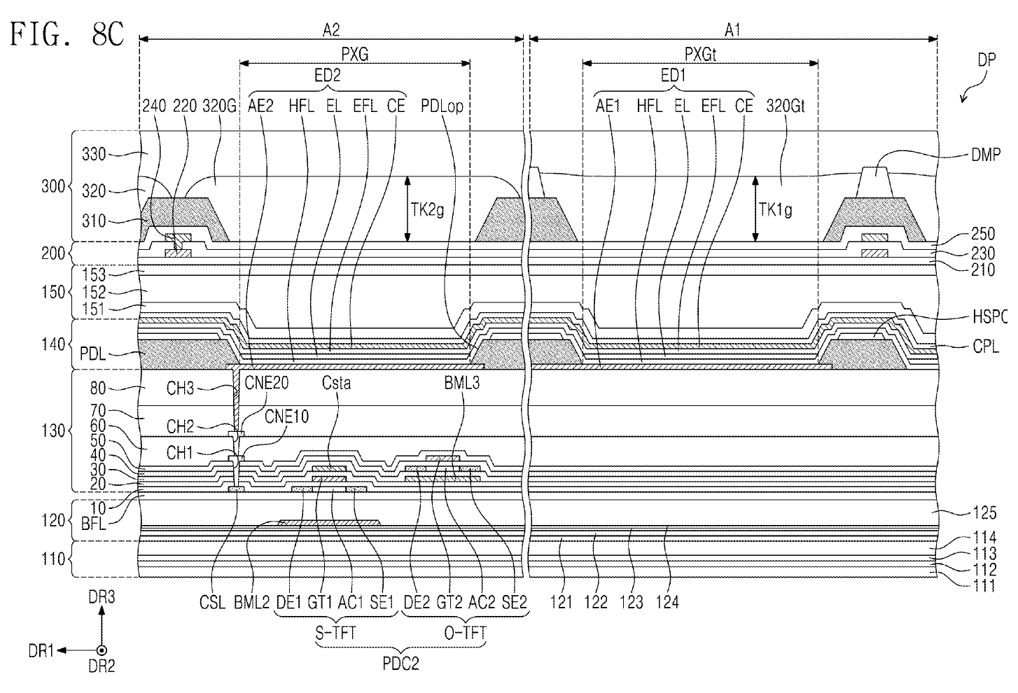

FIG. 7 is an enlarged plan view illustrating a partial region of a display panel DP (e.g., a region XX' of FIG. 6, which may be a region including a boundary between a first region A1 and a second region A2) according to one or more embodiments of the present disclosure. FIGS. 8A to 8C are enlarged cross-sectional views illustrating a partial region of the display panel illustrated in FIG. 7. FIG. 8A is a cross-sectional view illustrating the first region A1 of the display panel DP according to one or more embodiments of the present disclosure. FIG. 8B is a cross-sectional view illustrating the second region A2 of the display panel DP according to one or more embodiments of the present disclosure. FIG. 8C is a cross-sectional view simultaneously illustrating the first region A1 and the second region A2 of the display panel DP according to one or more embodiments of the present disclosure. Hereinafter, the present disclosure is described with refence to FIGS. 7 to 8C.

As illustrated in FIG. 7, a pixel PX may be provided in plurality, and the plurality of pixels PX may include first pixels PXR, second pixels PXG, and third pixels PXB. The first pixels PXR may be red light-emitting pixels, the second pixels PXG may be green light-emitting pixels, and the third pixels PXB may be blue light-emitting pixels.

In one or more embodiments of the present disclosure, the first pixels PXR, the second pixels PXG, and the third pixels PXB may be located in the second region A2. A planar shape of each of the first pixels PXR, the second pixels PXG, and the third pixels PXB illustrated in FIG. 7 may correspond to a shape of a light-emitting region defined in a light-emitting element. The light-emitting region may be a region defined by a pixel-defining opening that is defined in a pixel-defining film (e.g., PDL1 and/or PDL2).

Referring to FIGS. 8A and 8B, the display panel DP may include a display layer 100, a sensor layer 200, and an anti-reflection layer 300. The display layer 100 may include a base layer 110, a barrier layer 120, a circuit layer 130, an element layer 140, and an encapsulation layer 150.

The base layer 110 may include first to fourth sub-base layers 111, 112, 113, and 114.

The first sub-base layer 111 and the fourth sub-base layer 114 may each include at least one among a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Meanwhile, in this specification, a "~~based" resin may be considered as including a functional group of "~~". For example, the first and fourth sub-base layers 111 and 114 may each include polyimide.

The second sub-base layer 112 and the third sub-base layer 113 may each include an inorganic material. For example, the second sub-base layer 112 and the third sub-base layer 113 may each include at least one among silicon oxide, silicon nitride, silicon oxynitride, and amorphous silicon. For instance, the second sub-base layer 112 may include silicon oxynitride, and the third sub-base layer 113 may include silicon oxide.

The barrier layer 120 may be located on the base layer 110. The barrier layer 120 may include a plurality of sub-barrier layers 121, 122, 123, 124, and 125, a first lower light-blocking layer BML1 (FIG. 8A), and a second lower light-blocking layer BML2 (FIG. 8B).

The first and second lower light-blocking layers BML1 and BML2 may be referred to as first and second lower layers, first and second lower metal layers, first and second lower electrode layers, first and second lower shielding layers, first and second light-blocking layers, first and second metal layers, first and second electrode layers, first and second shielding layers, or first and second overlap layers.

The plurality of sub-barrier layers 121, 122, 123, 124, and 125 may include a first sub-barrier layer 121, a second sub-barrier layer 122, a third sub-barrier layer 123, a fourth sub-barrier layer 124, and a fifth sub-barrier layer 125 that are sequentially stacked in a direction further away from the base layer 110. The first to fifth sub-barrier layers 121, 122, 123, 124, and 125 may each include an inorganic material. For example, the first to fifth sub-barrier layers 121, 122, 123, 124, and 125 may each include at least one among silicon oxide, silicon nitride, silicon oxynitride, and amorphous silicon. For example, the first sub-barrier layer 121 may include silicon oxynitride, the second sub-barrier layer 122 may include silicon oxide, the third sub-barrier layer 123 may include amorphous silicon, the fourth sub-barrier layer 124 may include silicon oxide, and the fifth sub-barrier layer 125 may include silicon oxide.

The first lower light-blocking layer BML1 may be located in the first region A1, and the second lower light-blocking layer BML2 may be located in the second region A2. The first lower light-blocking layer BML1 and the second lower light-blocking layer BML2 may be electrically insulated from each other, and different signals may be respectively applied to the first lower light-blocking layer BML1 and the second lower light-blocking layer BML2. For example, a constant voltage with a voltage level (e.g., a predetermined voltage level) may be applied to the first lower light-blocking layer BML1, and a driving voltage provided to a second pixel circuit PDC2 may be provided to the second lower light-blocking layer BML2.

The first lower light-blocking layer BML1 and the second lower light-blocking layer BML2 may be located at a same layer, and may include the same material. For example, the first lower light-blocking layer BML1 and the second lower light-blocking layer BML2 may be located between the fourth sub-barrier layer 124 and the fifth sub-barrier layer 125. The first lower light-blocking layer BML1 and the second lower light-blocking layer BML2 may be covered by the fifth sub-barrier layer 125. Because the fifth sub-barrier layer 125 has the greatest thickness among the first to fifth sub-barrier layers 121, 122, 123, 124, and 125, the extent to which properties of transistors are changed due to the voltages provided to the first and second lower light-blocking layers BML1 and BML2 may be reduced.

The first lower light-blocking layer BML1 may have, or define, a first opening BMop that defines a transmission region TP. When an electrode opening CEop is formed in, or defined by, a common electrode CE, the first lower light-blocking layer BML1 may be a pattern that functions as a mask. For example, light irradiated toward the common electrode CE from a rear surface of the base layer 110 may pass through the first opening BMop of the first lower light-blocking layer BML1, and may reach a portion of each of the common electrode CE and a capping layer CPL. That is, a portion of the common electrode CE and the capping layer CPL may be removed by the light passing through the first opening BMop of the first lower light-blocking layer BML1. The light may be a laser beam.

A region of the first region A1 that is overlapping the first opening BMop of the first lower light-blocking layer BML1 may be defined as the transmission region TP, and a remaining region of the first region A1 may be defined as a light-emitting region EP. A first pixel electrode AE1 may be located in the light-emitting region EP, and the first pixel electrode AE1 may be spaced apart from the transmission region TP.

A buffer layer BFL may be located on (e.g., may be above) the barrier layer 120. The buffer layer BFL may be provided for both the first region A1 and the second region A2. The buffer layer BFL may reduce or prevent the likelihood of a phenomenon where metal atoms or foreign matters diffuse into a first semiconductor pattern from the base layer 110. In addition, the buffer layer BFL may allow the first semiconductor pattern to be substantially uniformly formed by controlling a rate at which heat is provided during a crystallization process for forming the first semiconductor pattern.

The buffer layer BFL may include a plurality of inorganic layers. For example, the buffer layer BFL may include a first sub-buffer layer containing silicon nitride, and a second sub-buffer layer located on the first sub-buffer layer and containing silicon oxide. The buffer layer BFL may not overlap (e.g., may be spaced apart from in plan view) the transmission region TP. That is, an opening corresponding to the transmission region TP may be defined in the buffer layer BFL. Because the buffer layer BFL is not provided to the transmission region TP, transmittance of the transmission region TP may be further improved.

The circuit layer 130 may be located on the buffer layer BFL, and the element layer 140 may be located on the circuit layer 130. FIG. 8A illustrates a cross-sectional view of a light-emitting element ED1 (hereinafter, first light-emitting element) and a portion of a first pixel circuit PDC1, which are located in the first region A1. FIG. 8B illustrates a cross-sectional view of a light-emitting element ED2 (hereinafter, second light-emitting element) and a portion of the second pixel circuit PDC2, which are located in the second region A2.

Referring to FIG. 8A, a silicon thin-film transistor S-TFT and an oxide thin-film transistor O-TFT of the first pixel circuit PDC1 are illustrated. Referring to FIG. 8B, a silicon thin-film transistor S-TFT and an oxide thin-film transistor O-TFT of the second pixel circuit PDC2 are illustrated. In the second region A2, the second lower light-blocking layer BML2 may overlap some of second type transistors, and may not overlap some of the others. For example, the second lower light-blocking layer BML2 may overlap a portion of the region where the second pixel circuit PDC2 is located, and a voltage provided to the second lower light-blocking layer BML2 may be synchronized with an operation of the second pixel circuit PDC2 to be provided.

The first semiconductor pattern may be located on the buffer layer BFL. The first semiconductor pattern may include a silicon semiconductor. For example, the silicon semiconductor may include amorphous silicon, polycrystalline silicon, and the like. For example, the first semiconductor pattern may include low temperature polysilicon.

FIGS. 8A and 8B illustrate only a portion of the first semiconductor pattern located on the buffer layer BFL, and the first semiconductor pattern may further be located in another region. The first semiconductor pattern may be arranged (e.g., in accordance with a particular or corresponding rule or arrangement pattern) across the pixels. The first semiconductor pattern may have different electrical properties depending on whether to be doped or not. The first semiconductor pattern may include a first region with high conductivity and a second region with low conductivity. The first region may be doped with an N-type dopant or a P-type dopant. A P-type transistor may include a doped region that is doped with the P-type dopant, and an N-type transistor may include a doped region that is doped with the N-type dopant. The second region may be an undoped region, or a lightly doped region as compared to the first region.

The conductivity of the first region may be greater than the conductivity of the second region, and the first region may substantially serve as an electrode or a signal line. The second region may substantially correspond to an active region (or channel) of a transistor. In other words, a portion of the semiconductor pattern may be the active region of the transistor, another portion may be a source or drain of the transistor, and still another portion may be a connection electrode or connection signal line.

A source region SE1, an active region AC1, and a drain region DE1 of the silicon thin-film transistor S-TFT may be formed from the first semiconductor pattern. The source region SE1 and the drain region DE1 may respectively extend in opposite directions from the active region AC1 on a cross section.

FIG. 8B illustrates a portion of a connection signal line CSL formed from the first semiconductor pattern.

The circuit layer 130 may include a plurality of inorganic layers and a plurality of organic layers. In one or more embodiments, first to fifth insulation layers 10, 20, 30, 40, and 50 that are sequentially stacked on the buffer layer BFL may be inorganic layers, and sixth to eighth insulation layers 60, 70, and 80 may be organic layers.

The first insulation layer 10 may be located on (e.g., above) the buffer layer BFL. The first insulation layer 10 may cover the first semiconductor pattern. The first insulation layer 10 may be an inorganic layer and/or an organic layer, and may have a single- or multi-layered structure. The first insulation layer 10 may include at least one among aluminum oxide, titanium oxide, silicon oxide, silicon nitride, silicon oxynitride, zirconium oxide, and hafnium oxide. The first insulation layer 10 may be a single layer of silicon oxide. The insulation layer of the circuit layer 130 to be described later as well as the first insulation layer 10 may have a single- or multi-layered structure.

A gate electrode GT1 of the silicon thin-film transistor S-TFT is located on the first insulation layer 10. The gate electrode GT1 may be a portion of a metal pattern. The gate electrode GT1 overlaps the active region AC1. The gate electrode GT1 may function as a mask in a process of doping the first semiconductor pattern. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, indium zinc oxide, or the like, but is not particularly limited thereto.

The second insulation layer 20 may be located on the first insulation layer 10, and may cover the gate electrode GT1. The second insulation layer 20 may be an inorganic layer, and may have a single- or multi-layered structure. The second insulation layer 20 may include at least one among silicon oxide, silicon nitride, and silicon oxynitride. The second insulation layer 20 may have a single layer structure including a silicon nitride layer.

The third insulation layer 30 may be located on the second insulation layer 20. The third insulation layer 30 may be an inorganic layer, and may have a single- or multi-layered structure. For example, the third insulation layer 30 may have a multi-layered structure including a silicon oxide layer and a silicon nitride layer. One electrode Csta of the first capacitor Cst may be located between the second insulation layer 20 and the third insulation layer 30. In addition, another electrode (e.g., gate electrode GT1) of the first capacitor Cst may be located between the first insulation layer 10 and the second insulation layer 20.

A second semiconductor pattern may be located on the third insulation layer 30. The second semiconductor pattern may include an oxide semiconductor. The oxide semiconductor may include a plurality of regions that are distinguished based on whether or not metal oxide is reduced. A region (hereinafter, a reduced region) where the metal oxide is reduced may have greater conductivity than a region (hereinafter, a non-reduced region) where the metal oxide is not reduced. The reduced region substantially serves as a source/drain of the transistor or a signal line. The non-reduced region substantially corresponds to an active region (or semiconductor region, channel) of the transistor. In other words, a portion of the second semiconductor pattern may be the active region of the transistor, another portion may be the source/drain region of the transistor, and still another portion may be a signal transmitting region.

A source region SE2, an active region AC2, and a drain region DE2 of the oxide thin-film transistor O-TFT may be formed from the second semiconductor pattern. The source region SE2 and the drain region DE2 may respectively extend in opposite directions from the active region AC2 on a cross section.

The oxide thin-film transistor O-TFT located in the first region A1 may overlap the first lower light-blocking layer BML1. Accordingly, light incident from a lower part of the display panel DP may be blocked by the first lower light-blocking layer BML1, and may not be provided to the active region AC2 of the oxide thin-film transistor O-TFT.

The oxide thin-film transistor O-TFT located in the second region A2 may not overlap the second lower light-blocking layer BML2. Accordingly, a layer may be added so as to block a lower portion of the oxide thin-film transistor O-TFT from light. For example, a third lower light-blocking layer BML3 may be located under the oxide thin-film transistor O-TFT located in the second region A2. The third lower light-blocking layer BML3 may be located between the second insulation layer 20 and the third insulation layer 30. The third lower light-blocking layer BML3 may include the same material as the one electrode Csta of the first capacitor Cst, and may be formed through the same process.

The fourth insulation layer 40 may be located on the third insulation layer 30. The fourth insulation layer 40 may cover the second semiconductor pattern. The fourth insulation layer 40 may be an inorganic layer, and may have a single- or multi-layered structure. The fourth insulation layer 40 may include at least one among aluminum oxide, titanium oxide, silicon oxide, silicon nitride, silicon oxynitride, zirconium oxide, and hafnium oxide. The fourth insulation layer 40 may have a single layer structure containing silicon oxide.

A gate electrode GT2 of the oxide thin-film transistor O-TFT is located on the fourth insulation layer 40. The gate electrode GT2 may be a portion of a metal pattern. The gate electrode GT2 overlaps the active region AC2. The gate electrode GT2 may function as a mask in a process of reducing the second semiconductor pattern.

The fifth insulation layer 50 may be located on the fourth insulation layer 40, and may cover the gate electrode GT2. The fifth insulation layer 50 may be an inorganic layer and/or an organic layer, and may have a single- or multi-layered structure. For example, the fifth insulation layer 50 may have a multi-layered structure including a silicon oxide layer and a silicon nitride layer.

A first connection electrode CNE10 (see FIG. 8B) may be located on the fifth insulation layer 50. The first connection electrode CNE10 may be connected to the connection signal line CSL through a first contact hole CH1 that penetrates the first to fifth insulation layers 10, 20, 30, 40, and 50.

A second opening ILop (see FIG. 8A) may be defined in the buffer layer BFL and at least some insulation layers among the plurality of insulation layers 10, 20, 30, 40, 50, 60, 70, and 80 that are included in the circuit layer 130. For example, the second opening ILop may be defined in the buffer layer BFL and the first to fifth insulation layers 10, 20, 30, 40, and 50. The second opening ILop may be defined in a region overlapping the transmission region TP. That is, because a portion, of each of the buffer layer BFL and the first to fifth insulation layers 10, 20, 30, 40, and 50, which overlaps the transmission region TP is removed, the transmittance of the transmission region TP may be improved.

A minimum width of the second opening ILop may be less than a minimum width of the first opening BMop. Side walls, of the buffer layer BFL and the first to fifth insulation layers 10, 20, 30, 40, and 50, which define the second opening ILop, may protrude further toward the transmission region TP than a side wall of the first lower light-blocking layer BML1.

The sixth insulation layer 60 may be located on the fifth insulation layer 50. The sixth insulation layer 60 may include an organic material, and the sixth insulation layer 60 may include a polyimide-based resin. For example, the sixth insulation layer 60 may include photosensitive polyimide. A second connection electrode CNE20 (see FIG. 8B) may be located on the sixth insulation layer 60. The second connection electrode CNE20 may be connected to the first connection electrode CNE10 through a second contact hole CH2 that penetrates the sixth insulation layer 60.

The sixth insulation layer 60 may be located in both the light-emitting region EP and the transmission region TP. The sixth insulation layer 60 may be referred to as a common organic layer. The sixth insulation layer 60 may fill a portion where the second opening ILop is defined. That is, the sixth insulation layer 60 may overlap the transmission region TP. The sixth insulation layer 60 may be provided to the transmission region TP, thereby reducing a stepped portion on an upper surface of the sixth insulation layer 60. When a stepped portion of the layers overlapping the transmission region TP is reduced, diffraction of light incident on the transmission region TP may be mitigated (or reduced). Accordingly, deformation of an image due to the diffraction is reduced, and thus quality of the image obtained from the camera module CCM (see FIG. 2A) may be improved.

The seventh insulation layer 70 may be located on the sixth insulation layer 60, and may cover the second connection electrode CNE20. The eighth insulation layer 80 may be located on the seventh insulation layer 70.

The sixth insulation layer 60, the seventh insulation layer 70, and the eighth insulation layer 80 may each be an organic layer. In this specification, the sixth insulation layer 60 may be referred to as a first organic insulation layer, the seventh insulation layer 70 may be referred to as a second organic insulation layer, and the eighth insulation layer 80 may be referred to as a third organic insulation layer. For example, the sixth insulation layer 60, the seventh insulation layer 70, and the eighth insulation layer 80 may each include a general-purpose polymer, such as benzocyclobutene (BCB), polyimide, hexamethyldisiloxane (HMDSO), polymethylmethacrylate (PMMA), or polystyrene (PS), a polymer derivative having a phenol-based group, an acrylate-based polymer, an imide-based polymer, an arylether-based polymer, an amide-based polymer, a fluorine-based polymer, a p-xylene-based polymer, a vinyl alcohol-based polymer, a blend thereof, and the like.

Referring to FIGS. 8A to 8C, the element layer 140 including the first pixel electrode AE1, a light-emitting element ED, a first pixel-defining film PDL1, and a second pixel-defining film PDL2 may be located on the circuit layer 130.

A first light-emitting element ED1 may be located in the first region A1 (FIG. 8A), and a second light-emitting element ED2 may be located in the second region A2 (FIG. 8B). The first light-emitting element ED1 may include the first pixel electrode AE1, a first functional layer HFL, a first light-emitting layer EL1, a second functional layer EFL, and a common electrode CE (or cathode). The second light-emitting element ED2 may include a second pixel electrode AE2, a first functional layer HFL, a second light-emitting layer EL2, a second functional layer EFL, and a common electrode CE (or cathode). The first functional layer HFL, the second functional layer EFL, and the common electrode CE may be provided in common to the first light-emitting element ED1 and the second light-emitting element ED2, and may be provided in common to other pixels PX.

The first pixel electrode AE1 and the second pixel electrode AE2 may be located on the eighth insulation layer 80. The first pixel electrode AE1 may be connected (or electrically connected) to the first pixel circuit PDC1. The second pixel electrode AE2 may be connected to the second pixel circuit PDC2. For example, the second pixel electrode AE2 may be connected to the second connection electrode CNE20 through a third contact hole CH3 that penetrates the seventh insulation layer 70 and the eighth insulation layer 80.

Meanwhile, the first pixel circuit PDC1 may also be located in the second region A2. Alternatively, the first pixel circuit PDC1 may also be common to any one second pixel circuit PDC2. Here, the first light-emitting element ED1 may be a copy element for any one second light-emitting element ED2. In this case, as illustrated in FIG. 8C, because the first pixel circuit PDC1 may not be located under the first light-emitting element ED1, light transmittance of the first region A1 may be improved. However, this is only an example, and a connection between the first light-emitting element ED1 and the first pixel circuit PDC1 may be variously formed and is not limited to any one embodiment.

The first pixel electrode AE1 and the second pixel electrode AE2 may each be a (semi)transmissive electrode or a reflective electrode. In one or more embodiments, the first pixel electrode AE1 and the second pixel electrode AE2 may each include a reflective layer, which is formed from silver, magnesium, aluminum, platinum, palladium, gold, nickel, neodymium, iridium, chrome, a compound thereof, or the like, and a transparent or translucent electrode layer formed on the reflective layer. The transparent or translucent electrode layer may include at least one selected from groups including indium tin oxide, indium zinc oxide, indium gallium zinc oxide, zinc oxide, or indium oxide, and aluminum-doped zinc oxide. For example, the first pixel electrode AE1 and the second pixel electrode AE2 may each include a multi-layered structure where silver indium tin oxide, silver, and indium tin oxide are sequentially stacked.

The pixel-defining film (e.g., PDL1 and/or PDL2) may be located on the eighth insulation layer 80. The pixel-defining film may have a property of absorbing light. For example, the pixel-defining film may have a color of black and may include a black coloring agent. The black coloring agent may include a black dye and a black pigment. The black coloring agent may include carbon black, metal, such as chrome, or an oxide thereof.

The pixel-defining film may include the first pixel-defining film PDL1 and the second pixel-defining film PDL2. The first pixel-defining film PDL1 may be located in the first region A1. The first region A1 may include the transmission regions TP and the light-emitting region EP, and the first pixel-defining film PDL1 may not overlap the transmission regions TP and may overlap the light-emitting region EP. The light-emitting region EP may be a region where the first light-emitting element ED1 is located. A first pixel-defining opening PDLop1 that exposes at least a portion of the first pixel electrode AE1 may be defined in the first pixel-defining film PDL1.

In one or more embodiments of the present disclosure, the first pixel-defining film PDL1 may be provided in plurality. The first pixel-defining films PDL1, which are provided in plurality, may be arranged spaced apart from each other in the first region A1. The first pixel-defining films PDL1 may be located in respective light-emitting units EDU. However, this is merely an example, and one or more embodiments of the present disclosure is not limited thereto. For example, the first pixel-defining film PDL1 may also have an interconnected structure within the first region A1, as with a division layer 310.

The first pixel-defining opening PDLop1 exposing at least a portion of the first pixel electrode AE1, a second pixel-defining opening PDLop2 exposing at least a portion of the second pixel electrode AE2, and a transmission-defining opening/the first opening BMop that defines a transmission region TP, may be included. Light-emitting regions of the first region A1 may be defined by the first pixel-defining openings PDLop1 defined in the pixel-defining film PDL1, and light-emitting regions of the second region A2 may be defined by the second pixel-defining openings PDLop2. For example, a light-emitting region PXA may be defined in the light-emitting element ED.

The second pixel-defining film PDL2 may cover the second region A2 and a portion of the first region A1. For example, pixel-defining openings PDLop2 corresponding to the first pixels PXR, the second pixels PXG, and the third pixels PXB in a one-to-one correspondence may be defined in the second pixel-defining film PDL2. Meanwhile, the second pixel-defining film PDL2 is illustrated as having a shape spaced apart from the first pixel-defining film PDL1, but this is illustrated. The pixel-defining film (e.g., PDL1 and PDL2) may be provided as an integrated shape where the second pixel-defining film PDL2 and the first pixel-defining film PDL1 are connected, and is not limited to any one embodiment.

A spacer HSPC (see FIG. 8B) may be located on the pixel-defining film. The spacer HSPC may cover a portion of the second region A2 and a portion of the first region A1 in the same manner as the pixel-defining film. A protruding spacer SPC may be located in the second region A2. The protruding spacer SPC may be located on the spacer HSPC. The protruding spacer SPC may have a circular shape on a plane, but is not limited thereto.

A height (or thickness) of the protruding spacer SPC may be greater than a height (or thickness) of the spacer HSPC. The height of the spacer HSPC may be about 0.1 μm to about 0.5 μm, and a total height of the spacer HSPC and the protruding spacer SPC may be about 1.1 μm to about 2.0 μm. However, the height of the spacer HSPC and the total height of the spacer HSPC and the protruding spacer SPC are not limited to the aforementioned examples.

The spacer HSPC and the protruding spacer SPC may have an integrated shape, and may be formed from the same material. For example, the spacer HSPC and the protruding spacer SPC may be formed through the same process by a halftone mask. However, this is merely an example, and the present disclosure is not limited thereto. For example, the spacer HSPC and the protruding spacer SPC may also include different materials, and may also be formed through separate processes. Meanwhile, this is illustrated, and at least one of the spacer HSPC or the protruding spacer SPC may be omitted in the display panel DP according to one or more embodiments of the present disclosure.

The first functional layer HFL may be located on the pixel electrode (e.g., AE1 and/or AE2), the pixel-defining film (e.g., PDL1 and/or PDL2), the spacer HSPC, and the protruding spacer SPC. The first functional layer HFL may include a hole transport layer (HTL), may include a hole injection layer (HIL), or may include both the hole transport layer and the hole injection layer.

The light-emitting layer EL may be located on the first functional layer HFL, and may be located in a region corresponding to the pixel-defining opening PDLop2 of the second pixel-defining film PDL2. The light-emitting layer EL may include an organic material, inorganic material, or organic-inorganic material that emits light of a color (e.g., a predetermined color). The light-emitting layer EL may be located in the second region A2.

The second functional layer EFL may be located on the first functional layer HFL, and may cover the light-emitting layer EL. The second functional layer EFL may include an electron transport layer (ETL), may include an electron injection layer (EIL), or may include both the electron transport layer and the electron injection layer. The second functional layer EFL may be located in the second region A2.

The common electrode CE may be located on the second functional layer EFL. The common electrode CE may be located in the first region A1 and the second region A2. In one or more embodiments of the present disclosure, the first pixel-defining film PDL1 may be located between the first pixel electrode AE1 and the common electrode CE. An electrode opening CEop overlapping the first opening BMop may be defined in the common electrode CE. A minimum width of the electrode opening CEop may be greater than a minimum width of the first opening BMop of the first lower light-blocking layer BML1.

The element layer 140 may further include the capping layer CPL located on the common electrode CE. The capping layer CPL may serve to improve light-emitting efficiency according to the concept of constructive interference. The capping layer CPL may include a material with a refractive index of about 1.6 or more with respect to light with a wavelength of, for example, about 589 nm. The capping layer CPL may be an organic capping layer containing an organic material, an inorganic capping layer containing an inorganic material, or a composite capping layer containing an organic material and inorganic material. For example, the capping layer may include a carbocyclic compound, a heterocyclic compound, an amine group-containing compound, porphine derivatives, phthalocyanine derivatives, naphthalocyanine derivatives, an alkali metal complex, an alkaline earth metal complex, or any combination thereof. The carbocyclic compound, the heterocyclic compound, and the amine group-containing compound may be selectively substituted with a substituent including O, N, S, Se, Si, F, Cl, Br, I, or any combination thereof.

A portion of the capping layer CPL overlapping the electrode opening CEop of the common electrode CE may be removed. A portion of the capping layer CPL including a portion overlapping the transmission region TP and a portion of the common electrode CE may be removed, and thus the light transmittance of the transmission region TP may be further improved.

The encapsulation layer 150 may be located on the element layer 140. The encapsulation layer 150 may include a first inorganic encapsulation layer 151, an organic encapsulation layer 152, and a second inorganic encapsulation layer 153 that are sequentially stacked, but the layers that constitute the encapsulation layer 150 are not limited thereto.

The first and second inorganic encapsulation layers 151 and 153 may protect the element layer 140 from moisture and oxygen, and the organic encapsulation layer 152 may protect the element layer 140 from foreign matters, such as dust particles. The first and second inorganic encapsulation layers 151 and 153 may include a silicon nitride layer, a silicon oxynitride layer, a silicon oxide layer, a titanium oxide layer, an aluminum oxide layer, or the like. The organic encapsulation layer 152 may include an acrylate-based organic layer, and is not limited thereto.

In one or more embodiments of the present disclosure, a maximum thickness of a portion of the organic encapsulation layer 152 overlapping the first region A1 may be greater than a maximum thickness of a portion of the organic encapsulation layer 152 overlapping the second region A2.

The sensor layer 200 may be located on the display layer 100. The sensor layer 200 may be referred to as a sensor, an input-sensing layer, or an input-sensing panel. The sensor layer 200 may include a sensor base layer 210, a first sensor conductive layer 220, an intermediate insulation layer 230, a second sensor conductive layer 240, and a cover layer 250.

The sensor base layer 210 may be directly located on the display layer 100. The sensor base layer 210 may be an inorganic layer including at least any one among silicon nitride, silicon oxynitride, and silicon oxide. Alternatively, the sensor base layer 210 may be an organic layer including an epoxy resin, an acrylic resin, or an imide-based resin. The sensor base layer 210 may have a single-layer structure, or have a multi-layer structure laminated along a third direction DR3.

The first sensor conductive layer 220 and the second sensor conductive layer 240 may each have a single-layer structure, or have a multi-layer structure laminated along the third direction DR3.

A conductive layer in a single-layer structure may include a metal layer or a transparent conductive layer. The metal layer may include molybdenum, silver, titanium, copper, aluminum, or an alloy thereof. The transparent conductive layer may include transparent conductive oxide, such as indium tin oxide, indium zinc oxide, zinc oxide, or indium zinc tin oxide. In addition, the transparent conductive layer may include a conductive polymer, such as PEDOT, metal nanowires, graphene, etc.

A conductive layer in a multi-layer structure may include metal layers. The metal layers may have a three-layer structure of, for example, titanium/aluminum/titanium. The conductive layer in the multi-layer structure may include at least one metal layer and at least one transparent conductive layer.

The intermediate insulation layer 230 may be located between the first sensor conductive layer 220 and the second sensor conductive layer 240. The intermediate insulation layer 230 may include an inorganic film. The inorganic film may include at least one among aluminum oxide, titanium oxide, silicon oxide, silicon nitride, silicon oxynitride, zirconium oxide, and hafnium oxide.

Alternatively, the intermediate insulation layer 230 may include an organic film. The organic film may include at least one among an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

The cover layer 250 may be located on the intermediate insulation layer 230, and may cover the second sensor conductive layer 240. The second sensor conductive layer 240 may include a conductive pattern. The cover layer 250 may cover the conductive pattern to reduce or eliminate probability of damage to the conductive pattern during a subsequent process.

The cover layer 250 may include an inorganic material. For example, the cover layer 250 may include silicon nitride, but is not particularly limited thereto.

The anti-reflection layer 300 may be located on the sensor layer 200. The anti-reflection layer 300 may include the division layer 310, a plurality of color filters 320, and a planarization layer 330. The division layer 310 and the color filters 320 are not located in the transmission region TP of the first region A1.

In one or more embodiments of the present disclosure, the division layer 310 may be omitted. In this case, the function of the division layer 310 may be replaced by the color filters 320. The cover layer 250 may be located between the division layer 310 and the second sensor conductive layer 240. The division layer 310 may reduce or prevent external light reflection caused by the second sensor conductive layer 240. A material that constitutes the division layer 310 is not particularly limited as long as the material absorbs light. The division layer 310 may be a layer with a black color, and in one or more embodiments, the division layer 310 may include a black coloring agent. The black coloring agent may include a black dye and a black pigment. The black coloring agent may include carbon black, metal, such as chrome, or an oxide thereof.

A division opening 310op (FIG. 8B) and a transmission opening 310opt (FIG. 8A) may be defined in the division layer 310. The division opening 310op may overlap the first light-emitting element ED1 or the second light-emitting element ED2, and may overlap the first pixel electrode AE1 or the second pixel electrode AE2.

The transmission opening 310opt of the division layer 310 may overlap the first opening BMop of the first lower light-blocking layer BML1. In addition, the transmission opening 310opt may not overlap the first pixel electrode AE1 (e.g., may be spaced from the first pixel electrode AE1 in plan view). An end of the division layer 310 in a region adjacent to the transmission region TP may protrude toward the transmission region TP further than an end of the first pixel-defining film PDL1 and an end of the common electrode CE. A minimum width of the transmission opening 310opt of the division layer 310 may be substantially the same as a minimum width of the first opening BMop of the first lower light-blocking layer BML1. That is, the end of the division layer 310 in the region adjacent to the transmission region TP may be substantially aligned with an end of the first lower light-blocking layer BML1. Meanwhile, in this specification, the wording that each component is “substantially aligned,” or a width, etc., of each component is “substantially the same” includes not only a case where each component is completely aligned or a width, etc., of each component has physically the same size, but also a case where each component is the same within a tolerance range that occurs during the process despite the same design.

The color filter 320 may be located overlapping the division opening 310op. The color filter 320 may transmit light provided from the light-emitting layer EL overlapping the color filter 320. The color filter 320 may include first to third color filters/transmission color filters 320t (hereinafter, first to third transmission color filters 320Rt, 320Gt, and 320Bt) located in the first region A1, and first to third color filters 320R, 320G, and 320B located in the second region A2. It is illustrated that the color filter 320 includes color filters with three different colors, but the number of colors that constitute the color filter 320 may vary, and is not limited to any one embodiment.

The first to third color filters 320R, 320G, and 320B may respectively filter incident light into first to third colors. The first to third color filters 320R, 320G, and 320B may include pigments or dyes with the first to third colors. For example, the first color may be red, the second color may be green, and the third color may be blue, but one or more embodiments is not limited thereto. The first to third transmission color filters 320Rt, 320Gt, and 320Bt may respectively include pigments or dyes with colors corresponding to the first to third color filters 320R, 320G, and 320B.

The first to third color transmission filters 320Rt, 320Gt, and 320Bt may overlap a respective first light-emitting element ED1 and overlap the first pixel-defining opening PDLop1 to have a shape corresponding thereto. In addition, the first to third color filters 320R, 320G, and 320B may overlap a respective second light-emitting element ED2 and have a shape corresponding to the second pixel-defining opening PDLop2. Accordingly, the first to third color filters 320R, 320G, and 320B and the first to third transmission color filters 320Rt, 320Gt, and 320Bt may have different shapes, on a plane, with respect to the corresponding colors. The first to third color filters 320R, 320G, and 320B may each have a circular shape in plan view, and the first to third transmission color filters 320Rt, 320Gt, and 320Bt may each have a quadrangular shape in plan view (e.g., see FIG. 7). In addition, first to third transmission color filters 320Rt, 320Gt, and 320Bt may have a greater area, on a plane, with respect to the corresponding colors than the first to third color filters 320R, 320G, and 320B. However, this is illustrated, and the shapes of the first to third color filters 320R, 320G, and 320B and the first to third transmission color filters 320Rt, 320Gt, and 320Bt may be formed into various shapes and sizes depending on the corresponding light-emitting elements. The above configuration is not limited to any one embodiment.

The planarization layer 330 may cover the division layer 310 and the color filters 320. The planarization layer 330 may include an organic material, and provide a flat surface on an upper surface of the planarization layer 330. In one or more embodiments, the planarization layer 330 may also be omitted.

The display panel DP according to one or more embodiments of the present disclosure may include a reinforcement pattern DMP (e.g., see FIG. 8A and 8C). The reinforcement pattern DMP may be located on the division layer 310 and may be covered by the planarization layer 330. The reinforcement pattern DMP may have a different shape from the division layer 310 on a plane. The reinforcement pattern DMP may have a closed loop shape, on a plane, which surrounds an edge of any one color filter among the transmission color filters 320Rt, 320Gt, and 320Bt located in the first region A1.

The reinforcement pattern DMP may be provided in plurality, spaced apart from each other. The reinforcement patterns DMP may each surround the second transmission color filter 320Gt on a plane. Because the second transmission color filter 320Gt has a quadrangular shape, the reinforcement pattern DMP may be formed into a quadrangular ring shape on a plane. However, this is illustrated, and the shape of the reinforcement pattern DMP may vary depending on the shape of the transmission color filter that the reinforcement pattern surrounds, and is not limited to any one embodiment.

Referring to FIG. 8C, the reinforcement pattern DMP may be located in the first region A1, and may not be located in, or may be omitted from, the second region A2. FIG. 8C illustrates both the second color filter 320G of the second region A2 and the second transmission color filter 320Gt of the first region A1, which are the corresponding color filters. An upper surface of the second transmission color filter 320Gt may have a different shape from an upper surface of the second color filter 320G. For example, the upper surface of the second color filter 320G may be relatively flat, and the upper surface of the second transmission color filter 320Gt may be relatively concave. Because the transmission opening 310opt exists in the first region A1, the area occupied by the division layer 310 may be relatively smaller than the area occupied by the division layer in the second region A2, so that it may be difficult to secure a sufficient thickness of the transmission color filter 320t. Accordingly, the upper surface of the second transmission color filter 320Gt located in the first region A1 may be formed to be relatively concave.

However, a thickness TK1g of the second transmission color filter 320Gt may be the same as, or substantially equal to, a thickness TK2g of the second color filter 320G. According to the present disclosure, the pixel-defining film (e.g., PDL1 and/or PDL2) and the reinforcement pattern DMP may function as a partition wall for containing the second transmission color filter 320Gt. The first region A1 may accommodate the division layer 310 with relatively low density, compared to the second region A2. A thickness of the second transmission color filter 320Gt may be secured more suitably due to the reinforcement pattern DMP located in the first region A1. Accordingly, even when the second transmission color filter 320Gt has the upper surface with a relatively concave shape, the thickness TK1g may be formed to be equivalent to the thickness TK2g of the second color filter 320G on account of a height of the partition wall increased by the pixel-defining film PDL1 and the reinforcement pattern DMP. Therefore, the color filter may be formed to have a substantially even thickness with respect to the corresponding color in the first region A1 and the second region A2, and thus luminance and a color tone of an image may be uniformly expressed.

Meanwhile, the reinforcement pattern DMP may have a color. That is, the reinforcement pattern DMP may include a pigment or dye. The reinforcement pattern DMP may have the same color as any one of the transmission color filters 320Rt, 320Gt, or 320Bt, and may be formed from the same material as the color filter. The reinforcement pattern DMP may have a red color, and may be formed from the same material as the first transmission color filter 320Rt. The display panel DP in which an area of a red color filter is substantially increased within the first region A1 may be provided, on account of the reinforcement pattern DMP according to one or more embodiments of the present disclosure. Accordingly, the anti-reflection layer 300 may filter an image, displayed in the display layer 100, to be more reddish. According to the present disclosure, because the reinforcement pattern DMP is further included, it is possible to express with a uniform color tone with respect to a bluish image. Therefore, the display panel DP may adjust the color tone of the image displayed in the first region A1 through an arrangement of the reinforcement pattern DMP and color design, and may uniformize a display property by improving a color deviation from the second region A2. In addition, according to the present disclosure, a variation in a color coordinate or a variation in front contrast luminance according to an angle in a white pattern, such as viewing angle color shift (VACS) may be improved, thereby providing the display panel DP with an improved display property.

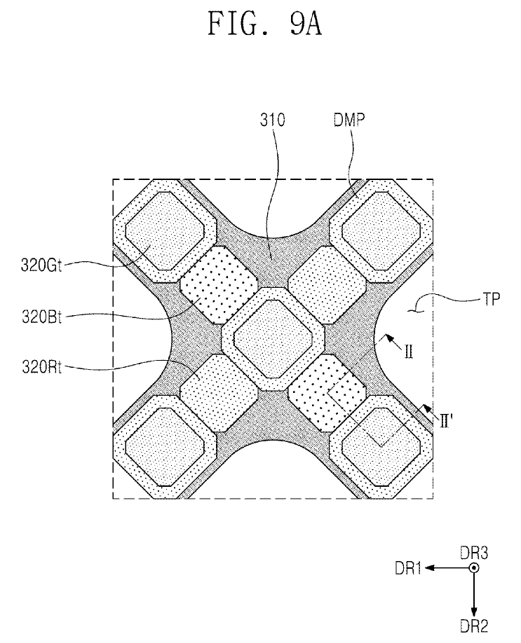

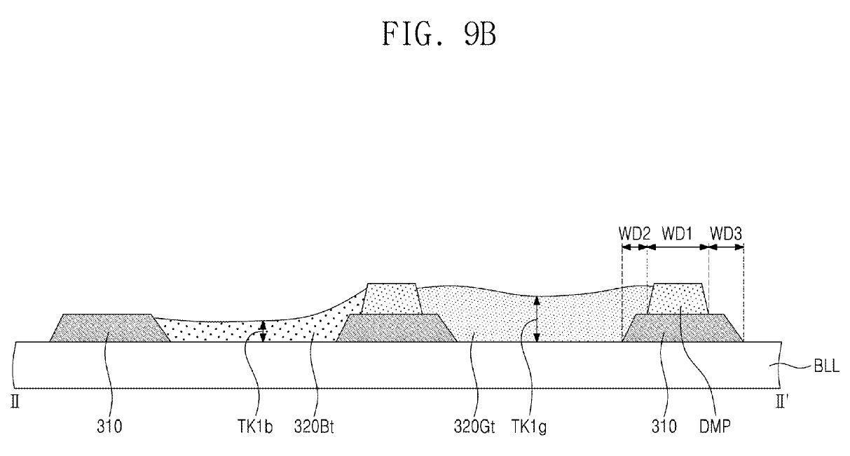

FIG. 9A is a plan view illustrating a portion of a display panel according to one or more embodiments of the present disclosure. FIG. 9B is a cross-sectional view schematically illustrating a partial region in FIG. 9A. For ease of explanation, FIGS. 9A and 9B illustrate only some of the components of the anti-reflection layer 300 (see FIG. 8A) in the first region A1 (see FIG. 7). Hereinafter, the present disclosure is described with reference to FIGS. 9A and 9B. Meanwhile, components that are the same as the components described with reference to FIGS. 1 to 8C will be denoted as the same reference numerals or symbols, and a duplicate explanation thereof will be omitted.

As illustrated in FIG. 9A, transmission color filters 320Rt, 320Gt, and 320Bt may be arranged along a diagonal direction. For example, a first transmission color filter 320Rt and a second transmission color filter 320Gt may be alternately arranged along a right diagonal direction (e.g., a first diagonal direction) crossing a first direction DR1 and a second direction DR2. The second transmission color filter 320Gt and a third transmission color filter 320Bt may be alternately arranged along a left diagonal direction (e.g., a second diagonal direction) crossing opposite directions of the first direction DR1 and the second direction DR2. A transmission region TP and the second transmission color filter 320Gt may be alternately arranged along the right diagonal direction or the left diagonal direction. In addition, the transmission region TP and the second transmission color filter 320Gt may be alternately arranged along the first direction DR1 or the second direction DR2.

Here, a reinforcement pattern DMP may be provided in plurality, and each of the reinforcement patterns may surround the second transmission color filter 320Gt on a plane. In a pixel arrangement illustrated in FIG. 9A, the first transmission color filter 320Rt may be located between the reinforcement patterns DMP arranged along the right diagonal direction, and the third transmission color filter 320Bt may be located between the reinforcement patterns DMP arranged along the left diagonal direction.

The second transmission color filter 320Gt among the transmission color filters 320t located in the first region A1 may have a different thickness (e.g., e.g., thickness TK1g) from the other transmission color filters 320Rt and 320Bt (e.g., thickness TK1b). The other transmission color filters 320Rt and 320Bt may be the color filters, among the color filters 320t located in the first region A1, which are not surrounded by the reinforcement pattern DMP. FIG. 9B illustrates a cross-sectional view of the second transmission color filter 320Gt and the third transmission color filter 320Bt that are adjacent to each other. A lower layer BLL, a layer where the anti-reflection layer 300 is located, may correspond to the aforementioned sensor layer 200 (see FIG. 8A), but is not limited thereto.

A thickness TK1g of the second transmission color filter 320Gt may be greater than a thickness TK1b of the third transmission color filter 320Bt. The thickness TK1g of the second transmission color filter 320Gt may be greater than thicknesses of the other transmission color filters 320Rt and 320Bt. The thickness TK1g of the second transmission color filter 320Gt may be controlled by a division layer 310 and the reinforcement pattern DMP. Because the division layer 310 and the reinforcement pattern DMP are stacked to function as a partition wall for containing the second transmission color filter 320Gt, the thickness TK1g of the second transmission color filter 320Gt may be formed to be greater than a thickness of the division layer 310.

A first width WD1 may correspond to a width of the reinforcement pattern DMP. The first width WD1 may be a main factor to control an area occupied by the reinforcement pattern DMP on a plane. The first width WD1 may be at least about 6 μm or more. When the first width WD1 is too small, it may be difficult to secure support force as a partition wall for containing the second transmission color filter 320Gt. When the first width WD1 is too large, it may be difficult to uniformize a color tone of an image in the first region A1 and transmittance of the first region A1 may be lowered.

A second width WD2 may be spacing between an inner side of the reinforcement pattern DMP and an inner side of the division layer 310. Each of the inner side of the reinforcement pattern DMP and the inner side of the division layer 310 may be a side in contact with the second transmission color filter 320Gt. The second width WD2 may be at least about 1 μm or more. When the second width WD2 is too small, the reinforcement pattern DMP may be located on a taper surface of the division layer 310, so that effect that the height of the partition wall is substantially increased due to formation of the reinforcement pattern DMP may be lowered.

A third width WD3 may be spacing between an outer side of the reinforcement pattern DMP and an outer side of the division layer 310. The outer side of the reinforcement pattern DMP may be opposed to the inner side of the reinforcement pattern DMP. The outer side of the division layer 310 may be a side where a transmission opening 310opt defining the transmission region TP is formed or defined. The third width WD3 may be at least about 2 μm or more. When the third width WD3 is too small, the reinforcement pattern DMP may be located on the taper surface of the division layer 310, or the reinforcement pattern DMP may flow down to the outer side of the division layer 310 when forming the reinforcement pattern DMP. Accordingly, the third width WD3 may be secured as sufficient spacing such that the reinforcement pattern DMP is stably formed without intruding into the transmission region TP.

Meanwhile, a thickness of the reinforcement pattern DMP (e.g., in a thickness direction, or in the third direction DR3) may be at least about 1 μm or more. According to the present disclosure, the thickness TK1g of the second transmission color filter 320Gt may be controlled by the thickness of the reinforcement pattern DMP. Accordingly, the reinforcement pattern DMP may secure a sufficient thickness such that the thickness TK1g of the second transmission color filter 320Gt reaches a required design value, and by controlling the thickness of the reinforcement pattern DMP, design of the thickness TK1g of the second transmission color filter 320Gt may be suitably accomplished.

The thickness TK1b of the third transmission color filter 320Bt may be less than the thickness TK1g of the second transmission color filter 320Gt. The third transmission color filter 320Btmay be formed to have a great thickness by the reinforcement pattern DMP in a side adjacent to the second transmission color filter 320Gt, but may be formed to have a small thickness by the division layer 310 in other regions. Because an upper surface of the third transmission color filter 320Bt is formed to be concave, the substantial thickness TK1b of the third transmission color filter 320Bt may be less than the thickness TK1g of the second transmission color filter 320Gt, and may be less than the thickness of the division layer 310.

According to the present disclosure, the reinforcement pattern DMP may have a shape surrounding only a corresponding color filter 320Gt among the transmission color filters located in the first region A1. Accordingly, the second transmission color filter 320Gt may have a different thickness from the other transmission color filters 320Rt and 320Bt. According to the present disclosure, a color tone of the image displayed in the first region A1 may be controlled by selectively controlling the thicknesses of the transmission color filters to be different.

Meanwhile, the reinforcement pattern DMP may be formed to have the same color as the first transmission color filter 320Rt. The first transmission color filter 320Rtmay have a green color. Accordingly, the reinforcement pattern DMP may have the green color, and may also be formed from the same material as the first transmission color filter 320Rt.

According to the present disclosure, because the reinforcement pattern DMP is further included, an area occupied by a pattern with a red color may be increased within the first region A1. Accordingly, the image displayed in the first region A1 may appear relatively reddish compared to an image displayed in a display layer 100. The display panel according to the present disclosure may adjust a color tone of the image by selecting the colors for the reinforcement pattern DMP variously. Therefore, the display panel that displays an image with a uniform color tone with respect to the first region A1 and the second region A2 may be provided.

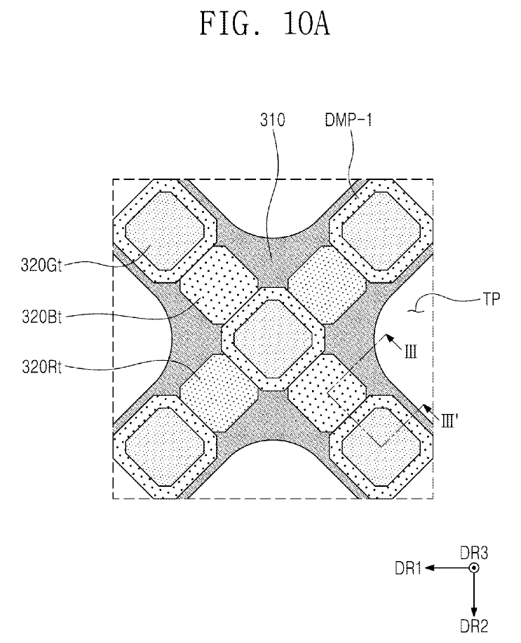

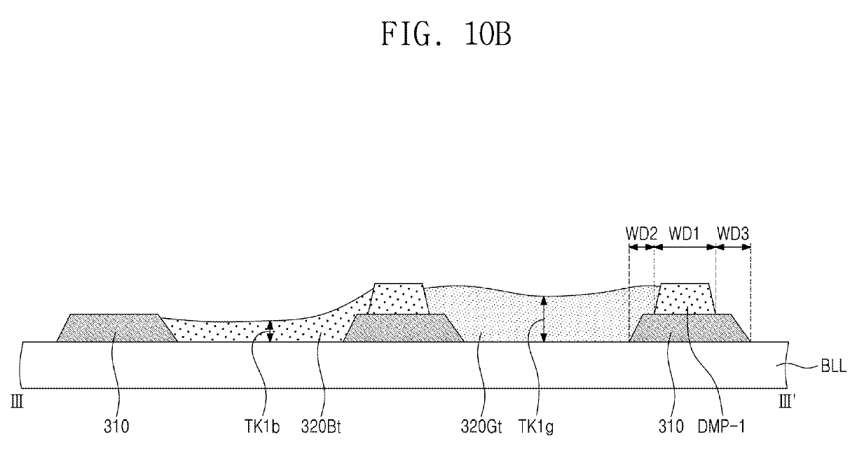

FIG. 10A is a plan view illustrating a portion of a display panel according to one or more embodiments of the present disclosure. FIG. 10B is a cross-sectional view schematically illustrating a partial region in FIG. 10A. FIGS. 10A and 10B illustrate regions respectively corresponding to those in FIGS. 9A and 9B. Hereinafter, the present disclosure is described with reference to FIGS. 10A and 10B. Meanwhile, components that are the same as the components described with reference to FIGS. 1 to 9B will be denoted as the same reference numerals or symbols, and a duplicate explanation thereof will be omitted.

As illustrated in FIGS. 10A and 10B, a reinforcement pattern DMP-1 may be provided in plurality, and each of the reinforcement patterns may surround a second transmission color filter 320Gt on a plane. Here, the reinforcement pattern DMP-1 may be formed to have the same color as a third transmission color filter 320Bt. The third transmission color filter 320Bt may have a blue color. Accordingly, the reinforcement pattern DMP-1 may have the blue color, and may also be formed from the same material as the third transmission color filter 320Bt.

According to the present disclosure, because the reinforcement pattern DMP-1 is further included, an area occupied by a pattern with a blue color may be increased within a first region A1. Accordingly, an image displayed in the first region A1 may appear relatively bluish compared to an image displayed in a display layer 100. A display panel according to the present disclosure may adjust a color tone of the image by selecting the colors for the reinforcement pattern DMP-1 variously. Therefore, the display panel that displays an image with a uniform color tone with respect to the first region A1 and a second region A2 may be provided.

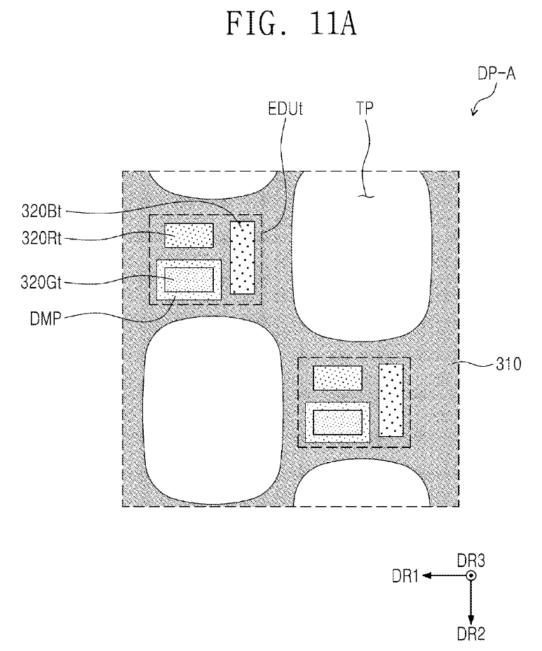

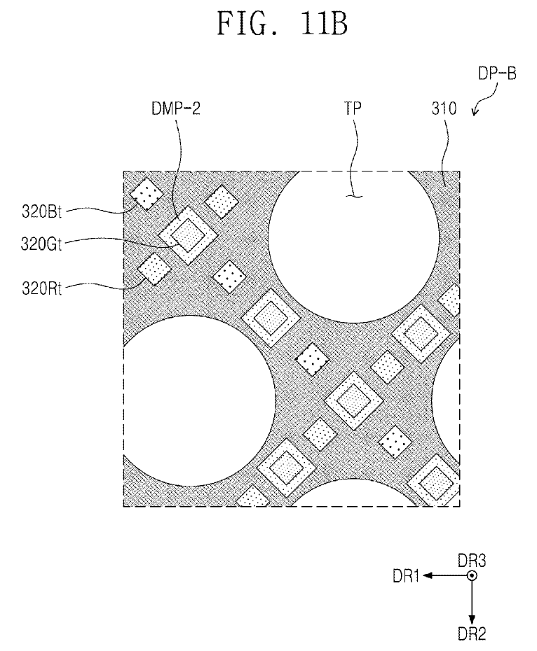

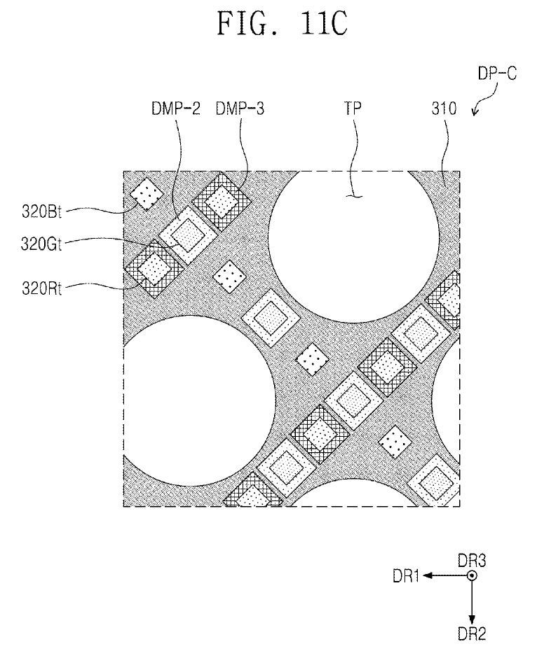

FIGS. 11A to 11C are plan views illustrating a portion of a display panel according to one or more embodiments of the present disclosure. For ease of explanation, FIGS. 11A to 11C illustrate only some of the components of the anti-reflection layer 300 (see FIG. 8A) to correspond to FIG. 9A. Hereinafter, various pixel arrangements according to the present disclosure will be described with reference to FIGS. 11A to 11C. Meanwhile, components that are the same as the components described with reference to FIGS. 1 to 10B will be denoted as the same reference numerals or symbols, and a duplicate explanation thereof will be omitted.

As illustrated in FIG. 11A, in a first region A1 of a display panel DP-A, a plurality of light-emitting units EDUt may be alternately arranged with a transmission region TP along a first direction DR1 or a second direction DR2. The light-emitting unit EDUt may be adjacent to the transmission regions TP in the first direction DR1 and the second direction DR2. The light-emitting unit EDUt may include a first transmission color filter 320Rt, a second transmission color filter 320Gt spaced apart from the first transmission color filter 320Rt in the second direction DR2, and a third transmission color filter 320Bt spaced apart from the first transmission color filter 320Rt in the first direction DR1. The first transmission color filter 320Rt and the second transmission color filter 320Gt may have a rectangular shape with long sides extending along the first direction DR1, and the third transmission color filter 320Bt may have a rectangular shape with long sides extending along the second direction DR2. The third transmission color filter 320Bt may be adjacent to both the first transmission color filter 320Rt and the second transmission color filter 320Gt in the first direction DR1.

A reinforcement pattern DMP may surround at least any one color filter among the first to third transmission color filters 320Rt, 320Gt, and 320Bt. The reinforcement pattern DMP may have a rectangular ring shape surrounding an edge of the second transmission color filter 320Gt.

As illustrated in FIG. 11B, in a first region A1 of a display panel DP-B, first to third transmission color filters 320Rt, 320Gt, and 320Bt may have an arrangement structure arranged in a diagonal direction. A pixel arrangement structure in the first region A1 of the display panel DP-B may correspond to the pixel arrangement structure illustrated in FIG. 9A.

Here, a reinforcement pattern DMP-2 may surround the second transmission color filter 320Gt. However, unlike the reinforcement pattern DMP illustrated in FIG. 8A, the reinforcement pattern DMP-2 may be spaced apart from the adjacent transmission color filters 320Rt and 320Bt. The reinforcement pattern DMP-2 may be only in contact with the second transmission color filter 320Gt and may not be in contact with the other transmission color filters 320Rt and 320Bt.

Alternatively, as illustrated in FIG. 11C, a display panel DP-C may further include an additional reinforcement pattern DMP-3. The additional reinforcement pattern DMP-3 may surround at least any one color filter among the other transmission color filters 320Rt and 320Bt. That is, the reinforcement pattern DMP-2 and the additional reinforcement pattern DMP-3 may respectively surround the transmission color filters with different colors. The reinforcement pattern DMP-2 may surround the second transmission color filter 320Gt, and the additional reinforcement pattern DMP-3 may surround the first transmission color filter 320Rt. According to the present disclosure, the additional reinforcement pattern DMP-3 may further be included, thereby controlling for securing a sufficient thickness for two or more different color filters.

The reinforcement pattern DMP-2 and the additional reinforcement pattern DMP-3 may have different colors. Alternatively, the reinforcement pattern DMP-2 and the additional reinforcement pattern DMP-3 may also have the same color. According to the present disclosure, a color tone of an image in the first region A1 may be suitably controlled by variously designing the colors of the reinforcement pattern DMP-2 and the additional reinforcement pattern DMP-3. Accordingly, a color deviation between the first region A1 and a second region A2 may be reduced, thereby providing the display panel with a uniform color tone.

According to the present disclosure, a color deviation between a first region including a transmission region and a second region adjacent thereto may be reduced, and an image with uniform luminance may be displayed, thereby improving a display property of an electronic apparatus.

In addition, according to the present disclosure, a color tone of the first region may be suitably controlled.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims to be described later. Therefore, the technical scope of the present disclosure is not to be limited to the contents stated in the detailed description of the specification, but should be determined by the claims, with functional equivalents thereof to be included therein.

What is claimed is:

1. An electronic apparatus comprising:
a display panel comprising a first region having a transmission region and a light-emitting region, and a second region adjacent to the first region; and
an electronic module under the display panel and overlapping the first region,
wherein the display panel comprises:
first light-emitting elements in the light-emitting region of the first region,
second light-emitting elements in the second region,
a division layer in the light-emitting region of the first region and in the second region,
transmission color filters in the first region, respectively overlapping the first light-emitting elements, respectively having a smaller area than the transmission region, and comprising a first transmission color filter and a second transmission color filter having a thickness that is less than a thickness of the first transmission color filter,
color filters in the second region and respectively overlapping the second light-emitting elements, and
a reinforcement pattern in the first region, above the division layer, and having a closed loop shape surrounding an edge of the first transmission color filter in plan view.

2. The electronic apparatus of claim 1, wherein the first transmission color filter has a green color, and
wherein the reinforcement pattern has a blue color.

3. The electronic apparatus of claim 1, wherein the first transmission color filter has a green color, and
wherein the reinforcement pattern has a red color.

4. The electronic apparatus of claim 1, wherein the reinforcement pattern has a same color as the second transmission color filter.

5. The electronic apparatus of claim 1, further comprising an additional reinforcement pattern surrounding a third transmission color filter of the transmission color filters having a different color from the first transmission color filter and the second transmission color filter.

6. The electronic apparatus of claim 1, further comprising an additional reinforcement pattern having a different color from the reinforcement pattern and surrounding a third transmission color filter of the transmission color filters having a different color from the first transmission color filter and the second transmission color filter.

7. The electronic apparatus of claim 1, further comprising an additional reinforcement pattern surrounding a third transmission color filter of the transmission color filters that has a different color from the first transmission color filter and the second transmission color filter,
wherein the reinforcement pattern is in contact with the second transmission color filter or the third transmission color filter.

8. The electronic apparatus of claim 1, further comprising a third transmission color filter of the transmission color filters has a different color from the first transmission color filter and the second transmission color filter,
wherein the reinforcement pattern is spaced apart from the second transmission color filter or the third transmission color filter in plan view.

9. The electronic apparatus of claim 1, further comprising a third transmission color filter of the transmission color filters having a different color from the first transmission color filter and the second transmission color filter,
wherein a thickness of the first transmission color filter is substantially equal to a thickness of, and has a same color as, a first color filter of the color filters.

10. The electronic apparatus of claim 1, wherein the transmission color filters are arranged along a diagonal direction, and
wherein the first transmission color filter and the transmission region are alternately arranged along a horizontal direction or a vertical direction.

11. The electronic apparatus of claim 1, wherein the transmission color filters are alternately arranged with the transmission region along a horizontal direction or a vertical direction,
wherein the second transmission color filter is spaced apart from the first transmission color filter in the vertical direction, and
wherein a third transmission color filter of the transmission color filters is spaced apart from the first transmission color filter and the second transmission color filter in the horizontal direction.

12. An electronic apparatus comprising:
a display panel comprising a first region having transmission regions, and a second region adjacent to the first region; and
an electronic module under the display panel and overlapping the first region,
wherein the display panel comprises:
first light-emitting elements in the first region;
second light-emitting elements in the second region;
a division layer defining first openings respectively overlapping the first light-emitting elements, second openings respectively overlapping the second light-emitting elements, and transmission openings respectively overlapping the transmission regions;
color filters respectively in the first openings;
transmission color filters respectively in the second openings and comprising a first transmission color filter having an upper surface that is different from upper surfaces of others of the transmission color filters; and
a reinforcement pattern in the first region, above the division layer, and having a closed loop shape surrounding the first transmission color filter.

13. The electronic apparatus of claim 12, wherein the reinforcement pattern comprises a same material as any of the transmission color filters.

14. The electronic apparatus of claim 13, wherein the reinforcement pattern comprises a different material from the first transmission color filter, and has a red color or a blue color.

15. The electronic apparatus of claim 12, wherein the reinforcement pattern and the first transmission color filter are provided in plurality,
wherein the transmission color filters further comprise second transmission color filters, and
wherein the reinforcement patterns comprise:
first patterns respectively surrounding the first transmission color filters and spaced apart; and
second patterns spaced apart from the first patterns, respectively surrounding the second transmission color filters, and having a same color as the first patterns.

16. The electronic apparatus of claim 12, wherein the reinforcement pattern and the first transmission color filter are provided in plurality,
wherein the transmission color filters further comprise second transmission color filters,
wherein the reinforcement patterns comprise first patterns respectively surrounding the first transmission color filters and spaced apart, and
wherein the reinforcement patterns further comprise second patterns spaced apart from the first patterns, respectively surrounding the second transmission color filters, and having different colors from the first patterns.

17. The electronic apparatus of claim 12, wherein the first transmission color filter has a different thickness from a first color filter of the color filters, and
wherein the transmission color filters comprise a second transmission color filter having a different thickness from the first transmission color filter.

18. The electronic apparatus of claim 12, wherein the first transmission color filter is provided in plurality,
wherein the transmission color filters have a different arrangement from the color filters, and comprise second transmission color filters and third transmission color filters having different colors from the first transmission color filters,
wherein the first transmission color filters and the second transmission color filters are alternately arranged along a first diagonal direction, and
wherein the first transmission color filters and the third transmission color filters are alternately arranged along a second diagonal direction crossing the first diagonal direction.

19. The electronic apparatus of claim 12, wherein the transmission color filters have a different arrangement from the color filters,
wherein the transmission color filters comprise a second transmission color filter and a third transmission color filter having different colors from the first transmission color filter, and
wherein the first transmission color filter and the second transmission color filter have a smaller area than the third transmission color filter.

20. The electronic apparatus of claim 12, wherein one of the transmission regions has a larger area than the first transmission color filter.
